(19) United States
(12) Patent Application Publication
(10) Pub. No.: US 2026/0334045 A1
(43) Pub. Date: Oct. 22, 2026

(54) LIGHT-EMITTING DEVICE AND ELECTRONIC EQUIPMENT

(71) Applicant: SONY SEMICONDUCTOR SOLUTIONS CORPORATION, Kanagawa (JP)

(72) Inventors: Kiwamu MIURA, Kanagawa (JP); Takashi TOYODA, Kanagawa (JP)

(73) Assignee: SONY SEMICONDUCTOR SOLUTIONS CORPORATION, Kanagawa (JP)

(21) Appl. No.: 19/105,950

(22) PCT Filed: Sep. 4, 2023
(86) PCT No.: PCT/JP2023/032254

§ 371 Date: Feb. 24, 2025

(30) Foreign Application Priority Data
Sep. 8, 2022 (JP) 2022-143240

(51) Int. Cl. H10K 59/80

(52) U.S. Cl. CPC H10K 59/80515; H10K 59/80521

(57) ABSTRACT

Provided is a light-emitting device capable of securing a carrier path in a direction away from a light-emitting region while increasing a contact area between a first electrode and a contact electrode. The light-emitting device includes a plurality of light-emitting elements in a light-emitting region, a contact electrode provided in a peripheral region located around the light-emitting region, and a first electrode extending from the light-emitting region to the peripheral region and connected to the contact electrode. The contact electrode includes a plurality of first structures at a portion where the first electrode is connected, and a plurality of the first structures extends in a direction away from the light-emitting region.

### TECHNICAL FIELD

The present disclosure relates to a light-emitting device and electronic equipment including the light-emitting device.

### BACKGROUND ART

Light-emitting devices each including a plurality of light-emitting elements in a light-emitting region are widely used. As one type of such light-emitting devices, a light-emitting device is known in which a contact electrode is provided in a peripheral region located around the light-emitting region, and a common electrode (for example, a common cathode) shared by the plurality of light-emitting elements extends from the light-emitting region to the peripheral region to connect to the contact electrode. For the light-emitting device having such a configuration, a technology has been proposed to increase a contact area between the common electrode and the contact electrode by providing a protrusion or recess in the contact electrode (see, for example, Patent Document 1).

### Citation List

### Patent Document

Patent Document 1: WO 2019/142582 A

### SUMMARY OF THE INVENTION

### Problems to be Solved by the Invention

When the protrusion or recess is provided in the contact electrode as described above, there is, however, a possibility that the common electrode is cut off by steps of the protrusion or recess, or the common electrode becomes thinner due to the step of the protrusion or recess. When the common electrode is brought into such a state due to the step, there is a possibility that it becomes difficult to secure a carrier path in a direction away from the light-emitting region.

It is therefore an object of the present disclosure to provide a light-emitting device capable of securing a carrier path in a direction away from a light-emitting region while increasing a contact area between a first electrode and a contact electrode, and electronic equipment including the light-emitting device.

### Solutions to Problems

In order to solve the above-described problems, a first light-emitting device according to the present disclosure is a light-emitting device including:
a plurality of light-emitting elements in a light-emitting region;
a contact electrode provided in a peripheral region located around the light-emitting region; and
a first electrode extending from the light-emitting region to the peripheral region and connected to the contact electrode, in which
the contact electrode includes a plurality of first structures at a portion where the first electrode is connected, and
the plurality of first structures extends in a direction away from the light-emitting region.

A second light-emitting device according to the present disclosure is a light-emitting device including:
a plurality of light-emitting elements in a light-emitting region;
a contact electrode provided in a peripheral region located around the light-emitting region; and
a first electrode extending from the light-emitting region to the peripheral region and connected to the contact electrode, in which
the contact electrode includes a plurality of structure groups at a portion where the first electrode is connected,
the plurality of structure groups is arranged at least in a circumferential direction of an outer periphery of the light-emitting region,
each of the structure groups includes a plurality of structures, and
the structure groups adjacent to each other in the circumferential direction are separated from each other.

Electronic equipment according to the present disclosure includes the first light-emitting device or the second light-emitting device.

### BRIEF DESCRIPTION OF DRAWINGS

FIG. 1 is a plan view of a display device for describing the overview.

FIG. 2 is a plan view of a display device according to a first embodiment.

FIG. 3 is a cross-sectional view taken along line III-III in FIG. 2.

FIG. 4 is an enlarged plan view of a part of a peripheral region.

FIG. 5 is a plan view of a display device according to a second embodiment.

FIG. 6 is a cross-sectional view taken along line VI-VI in FIG. 5.

FIG. 7 is a plan view of a display device according to a third embodiment.

FIG. 8 is an enlarged plan view of a part of a peripheral region.

FIG. 9 is a cross-sectional view taken along line IX-IX in FIG. 7.

FIG. 10 is a cross-sectional view of a display device according to a fourth embodiment.

FIG. 11 is a cross-sectional view of a display device according to a fifth embodiment.

FIG. 12 is a plan view of a display device according to Modification 1.

FIG. 13 is a cross-sectional view of a display device according to Modification 2.

FIG. 14 is a plan view of a display device according to Modification 3.

FIG. 15 is a cross-sectional view of a display device according to Modification 4.

FIG. 16 is a cross-sectional view of a display device according to Modification 5.

FIG. 17 is a cross-sectional view of a display device according to Modification 6.

FIGS. 18A, 18B, and 18C are each a conceptual diagram for describing a relationship among a normal line LN passing through a center of a light-emitting unit, a normal line LN′ passing through a center of a lens member, and a normal line LN″ passing through a center of a wavelength selection unit.

FIG. 19 is a conceptual diagram for describing a relationship among the normal line LN passing through the center of the light-emitting unit, the normal line LN′ passing through the center of the lens member, and the normal line LN″ passing through the center of the wavelength selection unit.

FIGS. 20A and 20B are each a conceptual diagram for describing a relationship among the normal line LN passing through the center of the light-emitting unit, the normal line LN′ passing through the center of the lens member, and the normal line LN″ passing through the center of the wavelength selection unit.

FIG. 21 is a conceptual diagram for describing a relationship among the normal line LN passing through the center of the light-emitting unit, the normal line LN′ passing through the center of the lens member, and the normal line LN″ passing through the center of the wavelength selection unit.

FIG. 22A is a schematic cross-sectional view for describing a first example of a resonator structure. FIG. 22B is a schematic cross-sectional view for describing a second example of the resonator structure.

FIG. 23A is a schematic cross-sectional view for describing a third example of the resonator structure. FIG. 23B is a schematic cross-sectional view for describing a fourth example of the resonator structure.

FIG. 24A is a schematic cross-sectional view for describing a fifth example of the resonator structure. FIG. 24B is a schematic cross-sectional view for describing a sixth example of the resonator structure.

FIG. 25 is a schematic cross-sectional view for describing a seventh example of the resonator structure.

FIG. 26A is a front view of a digital still camera. FIG. 26B is a rear view of the digital still camera.

FIG. 27 is a perspective view of a head-mounted display.

FIG. 28 is a perspective view of a television device.

FIG. 29 is a perspective view of a see-through head-mounted display.

FIG. 30 is a perspective view of a smartphone.

FIG. 31A is a diagram illustrating a cabin of a vehicle as viewed from a rear side to a front side of the vehicle. FIG. 31B is a diagram illustrating the cabin of the vehicle as viewed from an oblique rear side to an oblique front side of the vehicle.

### MODE FOR CARRYING OUT THE INVENTION

Embodiments of the present disclosure will be described in the following order with reference to the drawings. Note that the same or corresponding portions will be denoted by the same reference signs in all the drawings of the following embodiment.
1. General description of light-emitting device according to present disclosure
2. Overview
3. First embodiment (an example of display device)
4. Second embodiment (an example of display device)
5. Third embodiment (an example of display device)
6. Fourth embodiment (an example of display device)
7. Fifth embodiment (an example of display device)
8. Modifications
9. Relationship among normal lines passing through respective centers of light-emitting unit, lens member, and wavelength selection unit
10. Example of resonator structure
11. Application examples (examples of electronic equipment)

### 1. General Description of Light-Emitting Device According to Present Disclosure

A light-emitting device according to the present disclosure may be a display device, a lighting device, or another type of device. The display device may be an organic light emitting diode (OLED) display device.

In the light-emitting device according to the present disclosure, a first electrode may be an anode or cathode of a light-emitting element, or may be a common electrode connected to an anode or cathode of each of a plurality of light-emitting elements. The light-emitting element may be an OLED element.

In the light-emitting device according to the present disclosure, in a case where the first electrode serves as an anode, and a second electrode serves as a cathode, the plurality of light-emitting elements may include a plurality of anodes provided in a light-emitting region, one cathode extending from the light-emitting region to a peripheral region to connect to a contact electrode, and an organic light-emitting layer provided between the plurality of anodes and the one cathode.

In the light-emitting device according to the present disclosure, in a case where the first electrode serves as a cathode, and the second electrode serves as an anode, the plurality of light-emitting elements may include a plurality of anodes provided in the light-emitting region, one cathode extending from the light-emitting region to the peripheral region to connect to the contact electrode, and the organic light-emitting layer provided between the plurality of cathodes and the one anode.

In the light-emitting device according to the present disclosure, in a case where the first electrode serves as a common electrode connected to the anode or the cathode of each of the plurality of light-emitting elements, the plurality of light-emitting elements may include a plurality of types of light-emitting elements, and each of the plurality of types of light-emitting elements may be capable of emitting light of a different color. For example, the plurality of types of light-emitting elements may include a first light-emitting element capable of emitting red light, a second light-emitting element capable of emitting green light, and a third light-emitting element capable of emitting blue light.

The plurality of types of light-emitting elements may include an anode, a cathode, and an organic light-emitting layer, and the organic light-emitting layer may be provided between the anode and the cathode. The anode, the cathode, and the organic light-emitting layer in the plurality of types of light-emitting elements are individually provided for each light-emitting element. For example, the first light-emitting element may include an anode, a cathode, and a first organic light-emitting layer, and the first organic light-emitting layer may be capable of emitting red light. A second light-emitting element may include an anode, a cathode, and a second organic light-emitting layer, and the second organic light-emitting layer may be capable of emitting green light. A third light-emitting element may include an anode, a cathode, and a third organic light-emitting layer, and the third organic light-emitting layer may be capable of emitting blue light.

### 2. Overview

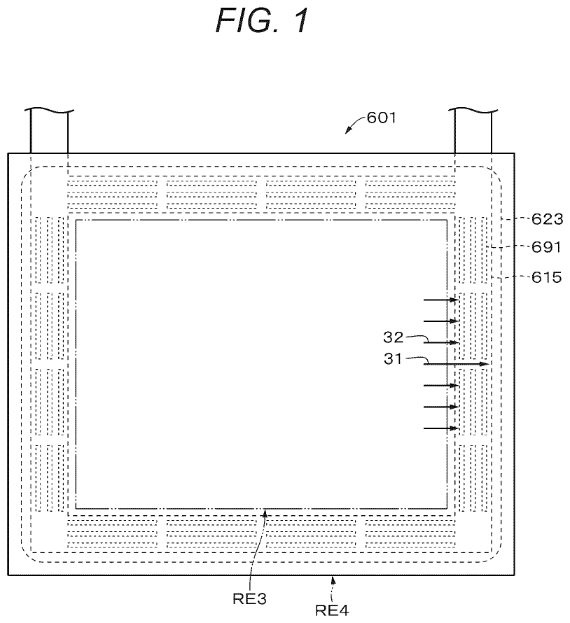

In a display device 601 illustrated in FIG. 1, a cathode 623 extends from an effective pixel region RE3 to a peripheral region RE4 to connect to a contact electrode (not illustrated). The contact electrode is connected to a wiring 615 by a plurality of contacts (not illustrated). The contact electrode includes a plurality of protrusions 691 at a portion to which the cathode 623 is connected in order to increase a contact area between a peripheral edge portion cathode 623 and the contact electrode. The plurality of protrusions 691 extends along a circumferential direction of an outer periphery of the effective pixel region RE3, and constitutes a plurality of examples arranged in a direction away from the effective pixel region RE3.

In the display device 601 configured as described above, the peripheral edge portion of the cathode 623 may be cut off by steps of the protrusions 691, or the peripheral edge portion of the cathode 623 may become thinner due to the steps of the protrusions 691. In a case where the peripheral edge portion of the cathode 623 is brought into such a state, a resistance value of the cathode 623 in the direction away from the effective pixel region RE3 increases. It is therefore difficult to secure a current path in the direction away from the effective pixel region RE3. In FIG. 1, an arrow 31 represents an image of a current path not inhibited by the protrusions 691, and an arrow 32 represents an image of a current path inhibited by the protrusions 691. Note that, in the following description, the arrows 31 and 32 each indicate an image of a current path.

The present inventors have thoroughly conducted, on the basis of the above points, studies for securing a current path (carrier path) in the direction away from the effective pixel region RE3 while increasing the contact area between the peripheral edge portion of the cathode 623 and the contact electrode. As a result, the present inventors have found a configuration where the plurality of protrusions extending in the direction away from the effective pixel region RE3 is provided in the contact electrode.

### 3. First Embodiment

### Configuration of Display Device 101

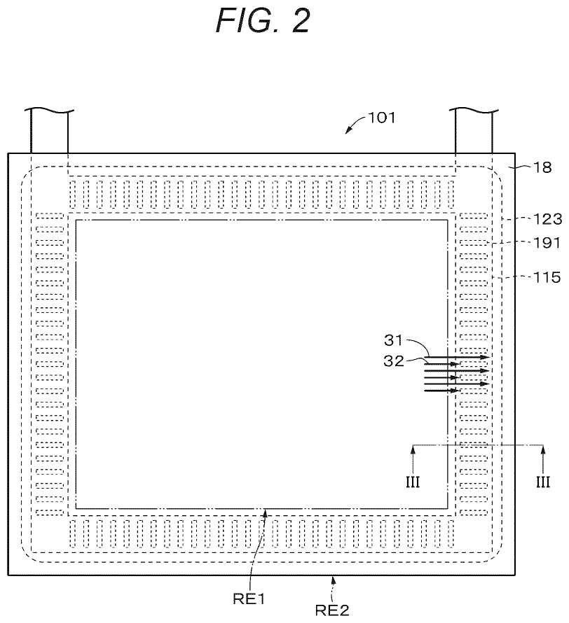

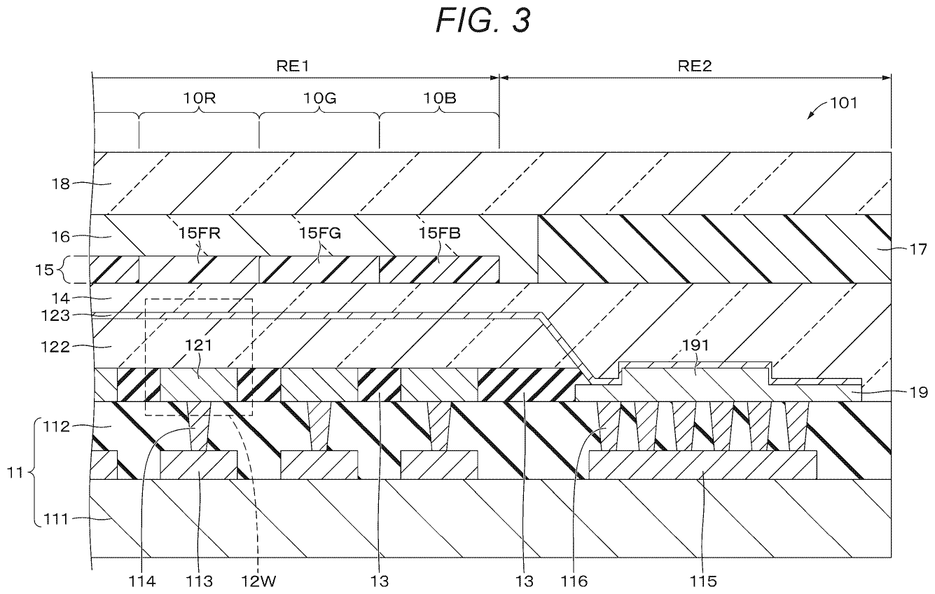

FIG. 2 is a plan view of a display device 101 according to the first embodiment. FIG. 3 is a cross-sectional view taken along line III-III in FIG. 2. The display device 101 includes an effective pixel region RE1 and a peripheral region RE2 located around the effective pixel region RE1. The effective pixel region RE1 is an example of the light-emitting region in the claims.

A plurality of sub-pixels 10R, 10G, and 10B is arranged two-dimensionally in the effective pixel region RE1 in a prescribed arrangement pattern. The prescribed arrangement pattern may be, for example, a stripe arrangement, a delta arrangement, a square arrangement, a mosaic arrangement, or another type of arrangement. A pad (not illustrated), a video display driver, and the like may be provided in the peripheral region RE2. A flexible printed circuit (FPC) (not illustrated) may be connected to the pad.

The sub-pixel 10R can emit red light (first light). The sub-pixel 10G can emit green light (second light). The sub-pixel 10B can emit blue light (third light). In the following description, the sub-pixels 10R, 10G, and 10B may be collectively referred to as sub-pixel 10 unless otherwise distinguished. Each pixel includes, for example, a plurality of sub-pixels 10R, 10G, and 10B adjacent to each other, or a plurality of sub-pixels 10R, 10G, 10B, and 10B adjacent to each other.

The display device 101 is an example of a light-emitting device. The display device 101 may be a top emission type OLED display device. The display device 101 may be a microdisplay. The display device 101 may be provided in an eyewear device such as a virtual reality (VR) device, a mixed reality (MR) device, or an augmented reality (AR) device, or may be provided in an electronic viewfinder (EVF), a small projector, or the like.

As illustrated in FIG. 3, the display device 101 includes a drive substrate 11, a plurality of light-emitting elements 12W, an insulating layer 13, a protective layer 14, a color filter 15, a filling resin layer 16, a seal portion 17, a cover glass 18, and a contact electrode 19.

Herein, of both the sides of each layer constituting the display device 101, a top side (display surface side) of the display device 101 may be referred to as first surface, and a bottom side (a side opposite to the display surface) of the display device 101 may be referred to as second surface. Herein, a peripheral edge portion of the first surface refers to a region with a predetermined width extending inward from the peripheral edge of the first surface, and a peripheral edge portion of the second surface refers to a region with a predetermined width extending inward from the peripheral edge of the second surface.

### Drive Substrate 11

The drive substrate 11 is a so-called backplane, and drives the plurality of light-emitting elements 12W. The drive substrate 11 includes, for example, a substrate 111 and an insulating layer 112 in this order.

A plurality of drive circuits (not illustrated), a plurality of wirings 113 and 115, and the like may be provided on the first surface of the substrate 111. The substrate 111 may include, for example, a semiconductor substrate on which a transistor and the like are easy to form, or a glass substrate or a resin substrate having low moisture and oxygen permeability. The semiconductor substrate includes, for example, amorphous silicon, polycrystalline silicon, monocrystalline silicon, or the like. The glass substrate includes, for example, high strain point glass, soda-lime glass, borosilicate glass, forsterite, lead glass, quartz glass, or the like. The resin substrate includes, for example, at least one selected from a group consisting of polymethyl methacrylate, polyvinyl alcohol, polyvinyl phenol, polyethersulfone, polyimide, polycarbonate, polyethylene terephthalate, polyethylene naphthalate, and the like.

The insulating layer 112 may be provided on the first surface of the substrate 111 to cover the plurality of drive circuits, the plurality of wirings 113 and 115, and the like for planarization. The insulating layer 112 may insulate the plurality of drive circuits, the plurality of wirings 113 and 115, and the like provided on the first surface of the substrate 111 from the plurality of light-emitting elements 12W. The wiring 115 may be connected to a pad (not illustrated).

The insulating layer 112 may include an organic insulating layer, an inorganic insulating layer, or a laminate of the organic insulating layer and the inorganic insulating layer. The organic insulating layer includes, for example, at least one selected from the group consisting of a polyimide resin, an acrylic resin, a novolac resin, and the like. The inorganic insulating layer includes, for example, at least one selected from the group consisting of silicon oxide (SiOₓ), silicon nitride (SiNₓ), silicon oxynitride (SiOₓN_{y}), and the like.

The insulating layer 112 includes a plurality of contacts 114 and 116 therein. Each contact 114 electrically connects the corresponding light-emitting element 12W and wiring 113. Each contact 116 electrically connects the corresponding contact electrode 19 and wiring 115. The contacts 114 and 116 include, for example, at least one selected from the group consisting of copper (Cu), titanium (Ti), and the like.

### Light-Emitting Element 12W

The light-emitting element 12W can emit white light under the control of the corresponding drive circuit and the like. The light-emitting element 12W is an OLED element. The OLED element may be a Micro-OLED (M-OLED) element. The light-emitting element 12W is included in each of the sub-pixels 10R, 10G, and 10B representing the corresponding color.

The plurality of light-emitting elements 12W is arranged two-dimensionally on the first surface of the drive substrate 11 in a prescribed arrangement pattern. The prescribed arrangement pattern is as described as the prescribed arrangement pattern of the plurality of sub-pixels 10. Each light-emitting element 12W includes an anode 121, an OLED layer 122, and a cathode 123. The anode 121, the OLED layer 122, and the cathode 123 are stacked on the first surface of the drive substrate 11. In the first embodiment, the anode 121 is an example of the second electrode in the claims, and the cathode 123 is an example of the first electrode in the claims.

### Anode 121

The anode 121 is provided on the second surface of the OLED layer 122. The anode 121 is an individual electrode individually provided for each of the plurality of light-emitting elements 12W in the effective pixel region RE1. That is, the anode 121 is separated between the light-emitting elements 12W adjacent to each other in an in-plane direction of the first surface of the drive substrate 11 in the effective pixel region RE1. When a voltage is applied between the anode 121 and the cathode 123, holes are injected from the anode 121 into the OLED layer 122.

The anode 121 may include, for example, a metal layer, or may include a metal layer and a transparent conductive oxide layer. In a case where the anode 121 includes a metal layer and a transparent conductive oxide layer, the transparent conductive oxide layer is preferably provided adjacent to the OLED layer 122 from the viewpoint of placing a layer with a high work function adjacent to the OLED layer 122.

The metal layer also functions as a reflective layer that reflects light generated in the OLED layer 122. The metal layer includes, for example, at least one metal element selected from a group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include AlNd and AlCu, for example.

An underlayer (not illustrated) may be provided adjacent to the second surface of the metal layer. The underlayer may have a capability of enhancing the crystalline orientation of the metal layer at the time of formation of the metal layer. The underlayer includes, for example, at least one metal element selected from a group consisting of titanium (Ti) and tantalum (Ta). The underlayer may include the at least one metal element described above as a constituent element of an alloy.

The transparent conductive oxide layer includes a transparent conductive oxide. The transparent conductive oxide includes, for example, at least one selected from a group consisting of a transparent conductive oxide including indium (hereinafter, referred to as “indium-based transparent conductive oxide”), a transparent conductive oxide including tin (hereinafter, referred to as “tin-based transparent conductive oxide”), and a transparent conductive oxide including zinc (hereinafter, referred to as “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO), and fluorine-doped indium oxide (IFO). Among these transparent conductive oxides, indium tin oxide (ITO) is particularly preferable. This is because indium tin oxide (ITO) has a particularly low barrier for hole injection into the OLED layer 122 in terms of a work function, and the drive voltage for the display device 101 can be particularly reduced accordingly. The tin-based transparent conductive oxide includes, for example, tin oxide, antimony-doped tin oxide (ATO), or fluorine-doped tin oxide (FTO). The zinc-based transparent conductive oxide includes, for example, zinc oxide, aluminum-doped zinc oxide (AZO), boron-doped zinc oxide, or gallium-doped zinc oxide (GZO).

### OLED Layer 122

The OLED layer 122 can emit white light. The OLED layer 122 is provided between the plurality of anodes 121 and the single cathode 123. The OLED layer 122 is a layer that extends across the light-emitting elements 12W adjacent to each other in the effective pixel region RE1 and is shared by the plurality of light-emitting elements 12W in the effective pixel region RE1.

The OLED layer 122 may include a laminate including an organic light-emitting layer, and in this case, a layer (for example, an electron injection layer) of the laminate may be an inorganic layer. The OLED layer 122 may be an OLED layer including a single-layer light-emitting unit, may be an OLED layer including two-layer light-emitting unit (tandem structure), or may be an OLED layer having another type of structure. The OLED layer including a single-layer light-emitting unit has a configuration in which, for example, a hole injection layer, a hole transport layer, a red light-emitting layer, a light-emitting separation layer, a blue light-emitting layer, a green light-emitting layer, an electron transport layer, and an electron injection layer are stacked on one another in this order from the anode 121 toward the cathode 123. The OLED layer including a two-layer light-emitting unit has a configuration in which, for example, a hole injection layer, a hole transport layer, a blue light-emitting layer, an electron transport layer, a charge generation layer, a hole transport layer, a yellow light-emitting layer, an electron transport layer, and an electron injection layer are stacked on one another in this order from the anode 121 toward the cathode 123.

The hole injection layer can enhance the efficiency of hole injection into each light-emitting layer and suppress leakage. The hole transport layer can enhance the efficiency of hole transport to each light-emitting layer. The electron injection layer can enhance the efficiency of electron injection into each light-emitting layer. The electron transport layer can enhance the efficiency of electron transport to each light-emitting layer. The light-emitting separation layer is a layer for adjusting carrier injection into each light-emitting layer, and light emission balance of each color is adjusted by injecting electrons or holes into each light-emitting layer through the light-emitting separation layer. The charge generation layer can individually supply electrons and holes to two light-emitting layers between which the charge generation layer is sandwiched.

When an electric field is applied to the red light-emitting layer, the green light-emitting layer, the blue light-emitting layer, and the yellow light-emitting layer, holes injected from the anode 121 or the charge generation layer and electrons injected from the cathode 123 or the charge generation layer are recombined together, and red light, green light, blue light, and yellow light are generated, respectively.

### Cathode 123

The cathode 123 is provided on the first surface of the OLED layer 122. The cathode 123 is a common electrode that extends across the light-emitting elements 12W adjacent to each other in the effective pixel region RE1 and is shared by the plurality of light-emitting elements 12W in the effective pixel region RE1. The cathode 123 extends from the effective pixel region RE1 to the peripheral region RE2. The second surface of the cathode 123 has its peripheral edge portion connected to the first surface of the contact electrode 19.

When a voltage is applied between the anode 121 and the cathode 123, electrons are injected from the cathode 123 into the OLED layer 122. The cathode 123 has transparency to white light emitted from the OLED layer 122. The cathode 123 is preferably a transparent electrode having transparency to visible light. Herein, visible light refers to light in a wavelength region of 360 nm to 830 nm.

The cathode 123 preferably includes a material having as high transparency as possible and a low work function in order to enhance light emission efficiency. The cathode 123 includes, for example, at least one of a metal layer or a transparent conductive oxide layer.

More specifically, the cathode 123 includes a single-layer film of a metal layer or a transparent conductive oxide layer or a multilayer film of a metal layer and a transparent conductive oxide layer. In a case where the cathode 123 includes such a multilayer film, the metal layer may be provided adjacent to the OLED layer 122 or the transparent conductive oxide layer may be provided adjacent to the OLED layer 122, but from the viewpoint of placing a layer with a low work function adjacent to the OLED layer 122, the metal layer is preferably provided adjacent to the OLED layer 122.

The metal layer includes, for example, at least one metal element selected from a group consisting of magnesium (Mg), aluminum (Al), silver (Ag), calcium (Ca), and sodium (Na). The metal layer may include the at least one metal element described above as a constituent element of an alloy. Specific examples of the alloy include an MgAg alloy, an MgAl alloy, an AlLi alloy, and the like. The transparent conductive oxide layer includes a transparent conductive oxide. As the transparent conductive oxide, a material similar to the transparent conductive oxide of the anode 121 described above can be exemplified.

### Contact Electrode 19

The contact electrode 19 is provided on the first surface of the drive substrate 11 in the peripheral region RE2. The contact electrode 19 may have a layer shape. The contact electrode 19 is an auxiliary electrode that connects the cathode 123 and the wiring 115. The contact electrode 19 has the first surface electrically connected to the peripheral edge portion of the second surface of the cathode 123. On the other hand, the contact electrode 19 has the second surface connected to the wiring 115 through the plurality of contacts 116 and the like.

The contact electrode 19 may have a closed loop shape surrounding the entire outer periphery of the effective pixel region RE1 in plan view, or may have a partially segmented loop shape partially surrounding the outer periphery of the effective pixel region RE1. Herein, the plan view means a plan view when an object is viewed from a direction perpendicular to the first surface.

The contact electrode 19 includes a plurality of protrusions 191 on the first surface connected to the peripheral edge portion of the cathode 123. Each protrusion 191 is an example of a structure. The peripheral edge portion of the cathode 123 may be provided on the first surface of the contact electrode 19 so as to follow the plurality of protrusions 191. Herein, the peripheral edge portion of the cathode 123 refers to a region with a predetermined width extending inward from the peripheral edge of the cathode 123. The plurality of protrusions 191 extends in the direction away from the effective pixel region RE1 in plan view. The plurality of protrusions 191 may be provided radially around the effective pixel region RE1.

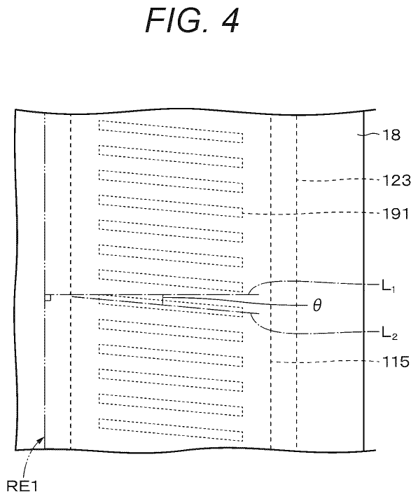

Herein, the direction away from the effective pixel region RE1 includes a direction perpendicular to the outer periphery of the effective pixel region RE1 (see FIG. 2) and a direction oblique to the outer periphery of the effective pixel region RE1 (see FIG. 4) in plan view. The plurality of protrusions 191 may include a plurality of protrusions 191 extending in the direction perpendicular to the outer periphery of the effective pixel region RE1 and a plurality of protrusions 191 extending in the direction oblique to the outer periphery of the effective pixel region RE1. In a case where the plurality of protrusions 191 includes a plurality of protrusions 191 extending in the direction oblique to the outer periphery of the effective pixel region RE1, the extending directions of the plurality of protrusions 191 may be the same, or may be two or more different directions.

An angle θ (see FIG. 4) formed by a perpendicular line L₁ perpendicular to the outer periphery of the effective pixel region RE1 and a central axis L₂ of each protrusion 191 extending in the direction oblique to the outer periphery of the effective pixel region RE1 is preferably ±10° or less, more preferably ±8° or less or ±6° or less, and more preferably ±5° or less, ±4° or less, ±3° or less, ±2° or less, ±1° or less, ±0.5° or less, or ±0.1° or less. Here, the “+” angle represents an angle in a clockwise direction relative to the perpendicular line L₁ perpendicular to the outer periphery of the effective pixel region RE1, and the “−” angle represents an angle in a counterclockwise direction relative to the perpendicular line L₁ perpendicular to the outer periphery of the effective pixel region RE1. The central axis L₂ of each protrusion 191 represents a straight line extending in the extending direction of the protrusion 191.

The plurality of protrusions 191 has, for example, an elongated shape in plan view. Specifically, the elongated shape may be, for example, a linear shape, a rectangular shape, an oval shape, or the like, or may be another type of shape. The oval shape includes an oblong shape, an elliptical shape, an egg shape, and the like. The plurality of protrusions 191 is arranged at intervals in the circumferential direction of the outer periphery of the effective pixel region RE1, that is, in the circumferential direction of the contact electrode 19. A distance between the protrusions 191 adjacent to each other in the circumferential direction of the outer periphery of the effective pixel region RE1 may be constant or variable.

The contact electrode 19 includes, for example, at least one of a metal layer or a metal oxide layer. More specifically, for example, the contact electrode 19 includes a single-layer film of a metal layer or a metal oxide layer, or a multilayer film of a metal layer and a metal oxide layer. The contact electrode 19 preferably has a configuration similar to the configuration of the anode 121. In this case, since the contact electrode 19 can be formed simultaneously with the anode 121, the process of manufacturing the display device 101 can be simplified.

As a material included in the contact electrode 19, a material similar to the material of the anode 121 can be exemplified. Specifically, as the material included in the metal layer of the contact electrode 19, a material similar to the material of the metal layer of the anode 121 can be exemplified, and as the material included in the metal oxide layer of the contact electrode 19, a material similar to the material of the metal oxide layer of the anode 121 can be exemplified.

An underlayer (not illustrated) may be provided adjacent to the second surface of the metal layer. As the material included in the underlayer, a material similar to the material of the underlayer of the anode 121 can be exemplified.

### Insulating Layer 13

The insulating layer 13 is provided on the first surface of the drive substrate 11 between the separated anodes 121. The insulating layer 13 insulates between the anodes 121 adjacent to each other. The insulating layer 13 includes a plurality of first openings. Each of the plurality of first openings is provided for the corresponding light-emitting element 12W. Each of the plurality of first openings may be provided on the first surface (surface adjacent to the OLED layer 122) of the corresponding anode 121. The anode 121 and the OLED layer 122 are in contact with each other through the first opening.

The insulating layer 13 is further provided between the anode 121 and the contact electrode 19 on the first surface of the drive substrate 11. The insulating layer 13 insulates between the anode 121 and the contact electrode 19. The insulating layer 13 includes a second opening. The second opening is provided corresponding to the contact electrode 19. The second opening may be provided on the first surface of the contact electrode 19 (the surface connected to the peripheral edge portion of the cathode 123). The contact electrode 19 and the peripheral edge portion of the cathode 123 are electrically connected through the second opening. The second opening may have a closed louve shape in a manner similar to the contact electrode 19.

The insulating layer 13 may be an organic insulating layer, an inorganic insulating layer, or a laminate of the organic insulating layer and the inorganic insulating layer. The organic insulating layer includes, for example, at least one selected from the group consisting of a polyimide resin, an acrylic resin, a novolac resin, and the like. The inorganic insulating layer includes, for example, at least one selected from the group consisting of silicon oxide (SiOₓ), silicon nitride (SiNₓ), silicon oxynitride (SiOₓN_{y}), and the like.

### Protective Layer 14

The protective layer 14 is provided on the first surface of the cathode 123. The protective layer 14 has transparency to white light emitted from the light-emitting elements 12W. The protective layer 14 preferably has transparency to visible light. The protective layer 14 can protect the plurality of light-emitting elements 12W and the like. For example, the protective layer 14 can block the plurality of light-emitting elements 12W from the outside air to suppress moisture ingress into the plurality of light-emitting elements 12W from the external environment. Furthermore, in a case where the cathode 123 includes a metal layer, the protective layer 14 may have a function of suppressing oxidation of the metal layer.

The protective layer 14 includes, for example, an inorganic material or a polymer resin having low hygroscopicity. The protective layer 14 may have a single layer structure or a multilayer structure. In a case where the thickness of the protective layer 14 is increased, the protective layer 14 preferably has a multilayer structure. This is to alleviate the internal stress in the protective layer 14. The inorganic material includes, for example, at least one selected from a group consisting of silicon oxide (SiOₓ), silicon nitride (SiNₓ), silicon oxynitride (SiOₓN_{y}), titanium oxide (TiOₓ), aluminum oxide (AlOₓ), and the like. The polymer resin includes, for example, at least one selected from the group consisting of a thermosetting resin, an ultraviolet curable resin, and the like. Specifically, the polymer resin includes, for example, at least one selected from the group consisting of an acrylic resin, a polyimide resin, a novolac resin, an epoxy resin, a norbornene resin, a parylene resin, and the like.

The protective layer 14 may include an atomic layer deposition (ALD) layer. It is possible for the protective layer 14 to further enhance the effect of suppressing moisture ingress by including the ALD layer. The ALD layer includes, for example, aluminum oxide (AlOₓ) or titanium oxide (TiOₓ).

### Color Filter 15

The color filter 15 is provided above the plurality of light-emitting elements 12W. More specifically, the color filter 15 is provided on the first surface of the protective layer 14 in the effective pixel region RE1. The color filter 15 is, for example, an on chip color filter (OCCF). The color filter 15 includes, for example, a plurality of red filter portions 15FR, a plurality of green filter portions 15FG, and a plurality of blue filter portions 15FB. Note that, in the following description, the red filter portions 15FR, the green filter portions 15FG, and the blue filter portions 15FB may be collectively referred to as filter portion 15F unless otherwise distinguished.

The plurality of filter portions 15F is arranged two-dimensionally on the first surface of the protective layer 14 in a prescribed arrangement pattern. The prescribed arrangement pattern is as described as the prescribed arrangement pattern of the plurality of sub-pixels 10. Each filter portion 15F is provided above the corresponding light-emitting element 12W. Each sub-pixel 10R includes the corresponding light-emitting element 12W and the corresponding red filter portion 15FR provided above the light-emitting element 12W. Each sub-pixel 10G includes the corresponding light-emitting element 12W and the corresponding green filter portion 15FG provided above the light-emitting element 12W. Each sub-pixel 10B includes the corresponding light-emitting element 12W and the corresponding blue filter portion 15FB provided above the light-emitting element 12W.

The red filter portion 15FR transmits red light out of the white light emitted from the light-emitting element 12W but absorbs light other than the red light. The green filter portion 15FG transmits green light out of the white light emitted from the light-emitting element 12W but absorbs light other than the green light. The blue filter portion 15FB transmits blue light out of the white light emitted from the light-emitting element 12W but absorbs light other than the blue light.

The red filter portion 15FR includes a red color resist, for example. The green filter portion 15FG includes a green color resist, for example. The blue filter portion 15FB includes a blue color resist, for example.

### Filling Resin Layer 16

The filling resin layer 16 is filled in between the color filter 15 and the cover glass 18. The filling resin layer 16 is provided inside the seal portion 17. The filling resin layer 16 has transparency to light of each color emitted through the color filter 15. The filling resin layer 16 preferably has transparency to visible light. The filling resin layer 16 may function as an adhesive layer that bonds the color filter 15 and the cover glass 18 together.

The filling resin layer 16 includes, for example, a curable resin. The curable resin includes at least one selected from the group consisting of a thermosetting resin, an ultraviolet curable resin, and the like. Note that the filling resin layer 16 is not limited to the thermosetting resin or the ultraviolet curable resin, and may include a curable resin of a type different from the thermosetting resin and the ultraviolet curable resin.

### Seal Portion 17

The seal portion 17 is provided between the peripheral edge portion of the first surface of the protective layer 14 and the peripheral edge portion of the second surface of the cover glass 18. The seal portion 17 bonds the peripheral edge portion of the first surface of the protective layer 14 and the peripheral edge portion of the second surface of the cover glass 18 together to seal a space between the peripheral edge portion of the protective layer 14 and the peripheral edge portion of the cover glass 18.

The seal portion 17 includes, for example, a curable resin. The curable resin includes, for example, at least one selected from the group consisting of a thermosetting resin, an ultraviolet curable resin, and the like. More specifically, the curable resin includes, for example, at least one selected from the group consisting of an epoxy resin, an acrylic resin, and the like. Note that the curable resin is not limited to the thermosetting resin or the ultraviolet curable resin, and may include a curable resin of a type different from the thermosetting resin and the ultraviolet curable resin.

### Cover Glass 18

The cover glass 18 is provided on the first surface of the filling resin layer 16 and the first surface of the seal portion 17. The cover glass 18 seals the first surface of the drive substrate 11 on which each member such as the plurality of light-emitting elements 12W is provided. The cover glass 18 has transparency to light of each color emitted through the color filter 15. The cover glass 18 preferably has transparency to visible light. The cover glass 18 is, for example, a glass substrate.

### Method for Manufacturing Display Device 101

Hereinafter, an example of a method for manufacturing the display device 101 according to the first embodiment will be described.

### Process of Forming Anode 121 and Contact Electrode 19

First, a metal layer and a metal oxide layer are sequentially formed on the first surface of the drive substrate 11 by, for example, a sputtering method, and then the metal layer and the metal oxide layer are patterned using, for example, a photolithography technique. As a result, the plurality of anodes 121 and the contact electrode 19 are formed on the first surface of the drive substrate 11. Next, the plurality of protrusions 191 is formed on the first surface of the contact electrode 19 using, for example, a photolithography technique.

### Process of Forming Insulating Layer 13

Next, the insulating layer 13 is formed on the first surface of the drive substrate 11 to cover the plurality of anodes 121 and the contact electrode 19 by, for example, a chemical vapor deposition (CVD) method. Next, the plurality of first openings and the single second opening are formed in the insulating layer 13 by, for example, a photolithography technique. As a result, the first surface of each anode 121 is exposed through the corresponding first opening, and the first surface of the contact electrode 19 is exposed through the second opening.

### Process of Forming OLED Layer 122

Next, a hole transport layer, a red light-emitting layer, a light-emitting separation layer, a blue light-emitting layer, a green light-emitting layer, an electron transport layer, and an electron injection layer are sequentially stacked on the first surface of the drive substrate 11 to cover the plurality of anodes 121 by, for example, a vapor deposition method, thereby forming the OLED layer 122.

### Process of Forming Cathode 123

Next, the cathode 123 is formed on the first surface of the OLED layer 122 and the first surface of the contact electrode 19 by, for example, a vapor deposition method or a sputtering method. As a result, the plurality of light-emitting elements 12W is formed on the first surface of the drive substrate 11, and the peripheral edge portion of the second surface of the cathode 123 is connected to the first surface of the contact electrode 19.

### Process of Forming Protective Layer 14

Next, the protective layer 14 is formed on the first surface of the cathode 123 by, for example, a CVD method or a vapor deposition method.

### Process of Forming Color Filter 15

Next, a coloring composition for forming green filter portions is applied onto the first surface of the protective layer 14, and, after pattern exposure by irradiation with ultraviolet rays through a photomask, development is performed to form the plurality of green filter portions 15FG. Next, a coloring composition for forming red filter portions is applied onto the first surface of the protective layer 14, and, after pattern exposure by irradiation with ultraviolet rays through a photomask, development is performed to form the plurality of red filter portions 15FR. Next, a coloring composition for forming blue filter portions is applied onto the first surface of the protective layer 14, and, after pattern exposure by irradiation with ultraviolet rays through a photomask, development is performed to form the plurality of blue filter portions 15FB. As a result, the color filter 15 is formed on the first surface of the protective layer 14.

### Sealing Process

Next, a sealing agent is applied onto the peripheral edge portion of the first surface of the protective layer 14 in a closed loop shape surrounding a display region R1 to form a frame, and then a filling resin is applied to the inside of the frame. Next, the cover glass 18 is placed on the filling resin and the sealing agent. Next, the sealing agent and the filling resin are cured by at least one of heat treatment or ultraviolet irradiation treatment, for example. As a result, the peripheral edge portion of the first surface of the protective layer 14 and the peripheral edge portion of the second surface of the cover glass 18 are bonded by the seal portion 17, and the filling resin layer 16 is formed inside the seal portion 17. Note that the method for curing the filling resin and the sealing agent is not limited to heat treatment or ultraviolet irradiation treatment, but may be a curing method that is neither heat treatment nor ultraviolet irradiation treatment. From above, the display device 101 illustrated in FIG. 3 is obtained.

### Actions and Effects

In the display device 101 according to the first embodiment, the contact electrode 19 includes the plurality of protrusions 191 on the first surface connected to the peripheral edge portion of the cathode 123. The plurality of protrusions 191 extends in the direction away from the effective pixel region RE1 in plan view and is arranged at intervals in the circumferential direction of the outer periphery of the effective pixel region RE1. With this configuration, as indicated by an arrow 31 in FIG. 2, a current path (carrier path) can be formed between the protrusions 191 adjacent to each other in the circumferential direction of the outer periphery of the effective pixel region RE1. It is thus possible to secure a current path in the direction away from the effective pixel region RE1 while increasing the contact area between the peripheral edge portion of the cathode 123 and the contact electrode 19. It is therefore possible to suppress the effects of voltage drop at the connection portion between the peripheral edge portion of the cathode 123 and the contact electrode 19 and suppress a decrease in luminance of the display device 101. Furthermore, it is possible to narrow the bezel of the display device 101 to reduce the size of the display device 101.

Even in a case where the display device 101 is increased in size or in luminance, it is possible to suppress the effects of voltage drop at the connection portion between the peripheral edge portion of the cathode 123 and the contact electrode 19.

### 4. Second Embodiment

### Configuration of Display Device 102

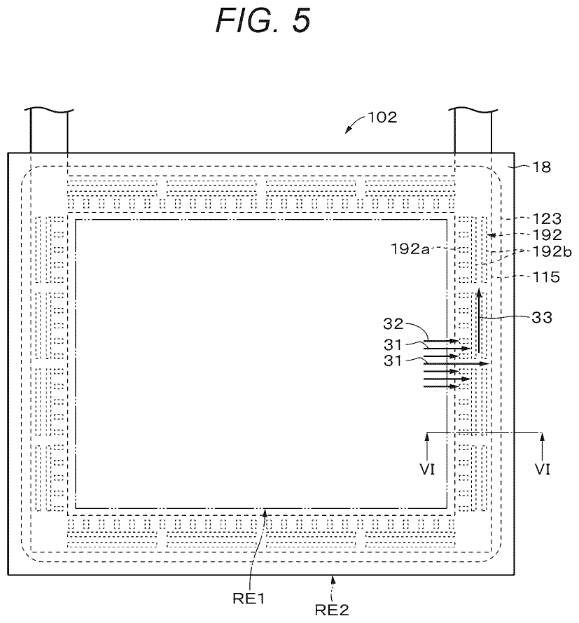

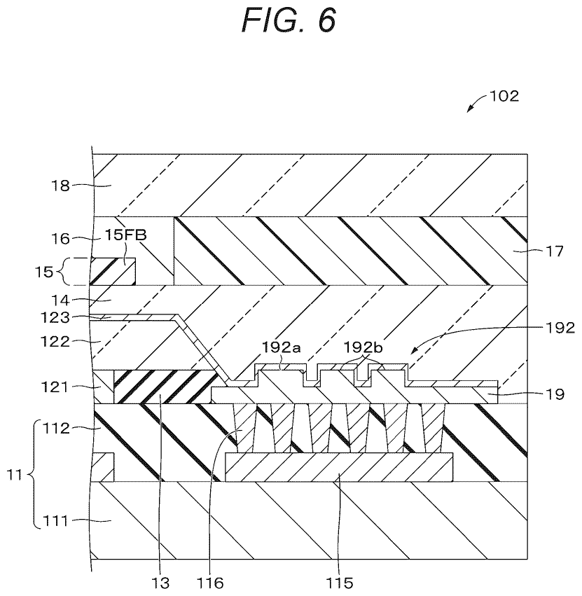

FIG. 5 is a plan view of a display device 102 according to the second embodiment. FIG. 6 is a cross-sectional view taken along line VI-VI in FIG. 5. The display device 102 is different from the display device 101 according to the first embodiment in that the contact electrode 19 includes a plurality of protrusion groups 192 instead of the plurality of protrusions 191. Each protrusion group 192 is an example of the structure group in the claims.

### Protrusion Group 192

The plurality of protrusion groups 192 is arranged at intervals in the circumferential direction of the outer periphery of the effective pixel region RE1, that is, in the circumferential direction of the contact electrode 19 in plan view. A distance between the protrusion groups 192 adjacent to each other in the circumferential direction of the outer periphery of the effective pixel region RE1 may be constant or variable.

Each protrusion group 192 includes a plurality of first protrusions 192a and a plurality of second protrusions 192b. In the second embodiment, an example where each protrusion group 192 includes a plurality of first protrusions 192a and a plurality of second protrusions 192b will be described, but each protrusion group 192 may include a plurality of first protrusions 192a and one second protrusion 192b.

### First Protrusion 192a

The plurality of first protrusions 192a is provided closer to the effective pixel region RE1 than the plurality of second protrusions 192b. Each first protrusion 192a is an example of the first structure in the claims. The first protrusion 192a is similar to the protrusion 191 in the first embodiment. Note that the first protrusion 192a may be shorter than the protrusion 191 in the first embodiment.

### Second Protrusion 192b

The plurality of second protrusions 192b is provided closer to the peripheral edge of the display device 101 than the plurality of first protrusions 192a. Each second protrusion 192b is an example of the second structure in the claims. The second protrusion 192b extends in a direction approximately perpendicular to the extending direction of the first protrusion 192a (that is, in a direction approximately the same as the circumferential direction of the effective pixel region RE1) in plan view.

Herein, the direction approximately perpendicular to the extending direction refers to a direction forming an angle between 80° and 100°, inclusive, with the extending direction. The angle formed between the extending direction and the direction approximately perpendicular to the extending direction may be, for example, between 82° and 98°, between 84° and 96°, between 85° and 95°, between 86° and 94°, between 87° and 93°, between 88° and 92°, between 89° and 91°, between 89.5° and 90.5°, or between 89.9° and 90.1°, all inclusive.

The plurality of second protrusions 192b each has, for example, an elongated shape in plan view. As a specific example of the elongated shape, a shape similar to the shape of the protrusion 191 in the first embodiment can be exemplified. The plurality of second protrusions 192b is arranged at intervals in the direction away from the effective pixel region RE1. In a case where the protrusion group 192 includes three or more second protrusions 192b, a distance between the second protrusions 192b adjacent to each other in the direction away from the effective pixel region RE1 may be constant or variable.

Among the plurality of second protrusions 192b, the second protrusion 192b closest to the effective pixel region RE1 may be separated from one end of each of the plurality of first protrusions 192a, or may be connected to one end of each of the plurality of first protrusions 192a. FIG. 5 illustrates an example where the second protrusion 192b closest to the effective pixel region RE1 among the plurality of second protrusions 192b is separated from the plurality of first protrusions.

### Actions and Effects

In the display device 102 according to the second embodiment, the plurality of protrusion groups 192 is arranged at intervals in the circumferential direction of the outer periphery of the effective pixel region RE1. Furthermore, the plurality of first protrusions 192a included in the plurality of protrusion groups 192 extends in the direction away from the effective pixel region RE1 in plan view and is arranged at intervals in the circumferential direction of the outer periphery of the effective pixel region RE1. With this configuration, as indicated by an arrow 31 in FIG. 5, a current path (carrier path) can be formed between the protrusion groups 192 adjacent to each other in the circumferential direction of the outer periphery of the effective pixel region RE1 and between the first protrusions 192a adjacent to each other in the circumferential direction of the outer periphery of the effective pixel region RE1. It is thus possible to secure a current path in the direction away from the effective pixel region RE1 while increasing the contact area between the cathode 123 and the contact electrode 19.

In the display device 102 according to the second embodiment, the plurality of second protrusions 192b included in the plurality of protrusion groups 192 extends in the direction approximately perpendicular to the extending direction of the first protrusions 192a (that is, in the direction approximately the same as the circumferential direction of the effective pixel region RE1) in plan view and is arranged at intervals in the direction away from the effective pixel region RE1. With this configuration, as indicated by an arrow 33 in FIG. 5, a current path (carrier path) can be formed between the second protrusions 192b adjacent to each other in the direction approximately perpendicular to the extending direction of the first protrusions 192a. It is thus possible to secure a current path in the circumferential direction of the effective pixel region RE1.

### 5. Third Embodiment

### Configuration of Display Device 103

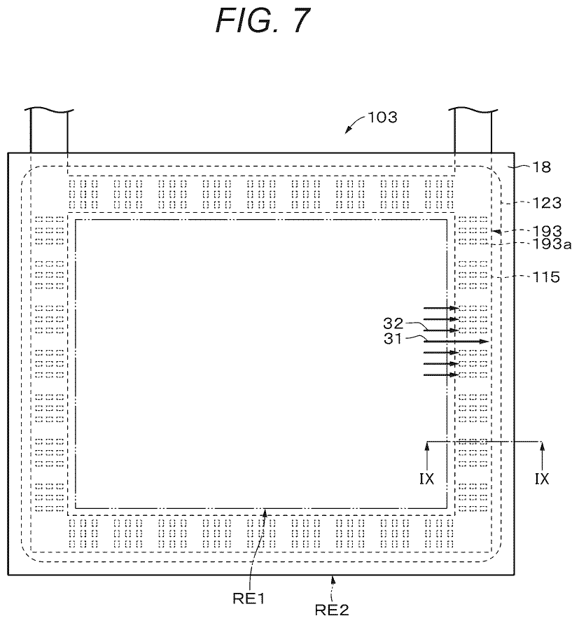

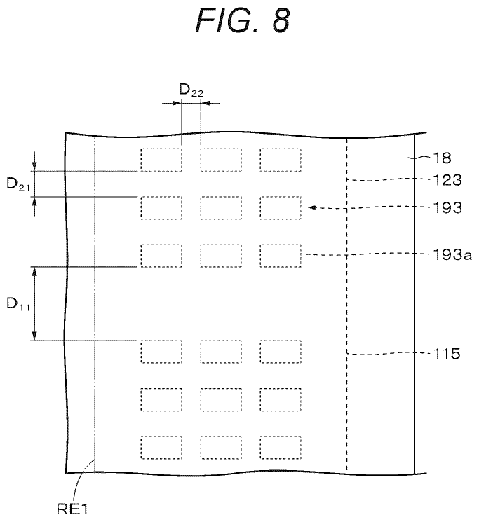

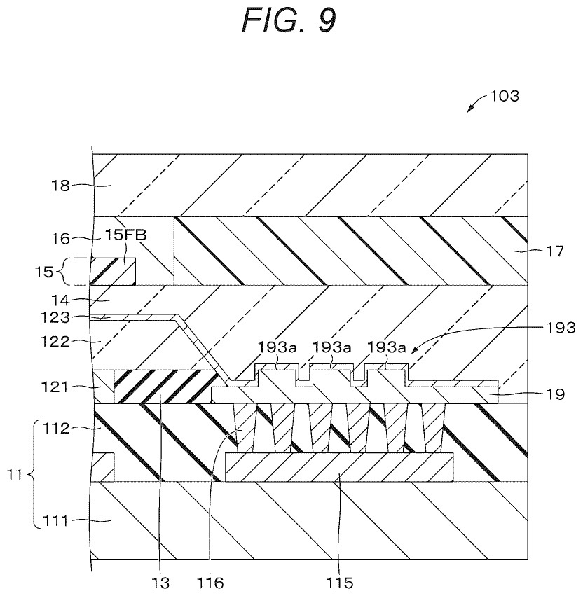

FIG. 7 is a plan view of a display device 103 according to the third embodiment. FIG. 8 is an enlarged plan view of a part of a peripheral region RE2 in FIG. 7. FIG. 9 is a cross-sectional view taken along line IX-IX in FIG. 7. The display device 103 is different from the display device 101 (see FIG. 2) according to the first embodiment in that the contact electrode 19 includes a plurality of protrusion groups 193 instead of the plurality of protrusions 191. Each protrusion group 193 is an example of the structure group in the claims.

### Protrusion Group 193

The plurality of protrusion groups 193 is arranged at intervals in the circumferential direction of the outer periphery of the effective pixel region RE1, that is, in the circumferential direction of the contact electrode 19 in plan view. A distance D between the protrusion groups 193 adjacent to each other in the circumferential direction of the outer periphery of the effective pixel region RE1 may be constant or variable. Each protrusion group 193 includes a plurality of protrusions 193a.

### Protrusion 193a

The plurality of protrusions 193a may be arranged two-dimensionally on the first surface of the contact electrode 19 in a prescribed arrangement pattern. The prescribed arrangement pattern may be a matrix pattern, a checkerwise pattern, or the like, or may be another type of arrangement pattern.

The plurality of protrusions 193a may be arranged at intervals D₂₁ in the circumferential direction of the outer periphery of the effective pixel region RE1 in plan view. The distance D₂₁ between the protrusions 193a adjacent to each other in the circumferential direction of the outer periphery of the effective pixel region RE1 may be constant or variable.

The plurality of protrusions 193a may be arranged at intervals D₂₂ in the direction away from the effective pixel region RE1 in plan view. The distance D₂₂ between the protrusions 193a adjacent to each other in the direction away from the effective pixel region RE1 may be constant or variable. The heights of the plurality of protrusions 193a may be approximately the same or different.

For example, each protrusion 193a may have a dot shape in plan view. The dot shape may include, for example, a circular shape, an elliptical shape, and a polygonal shape in plan view, or may include another type of shape. The protrusion 193a may have, for example, an approximately columnar shape, an approximately frustum shape, an approximately cone shape, or an approximately dome shape, or may have another type of shape. The plurality of protrusions 193a may include two or more types of protrusions 193a.

Relationship Among Distance D₁₁, Distance D₂₁, and Distance D₂₂

The distance D₁₁ between the protrusion groups 193 adjacent to each other in the circumferential direction of the outer periphery of the effective pixel region RE1 is preferably greater than the distance D₂₁ between the protrusions 193a adjacent to each other in the circumferential direction of the outer periphery of the effective pixel region RE1. With this configuration, a current flow through between the protrusion groups 193 adjacent to each other in the circumferential direction of the outer periphery of the effective pixel region RE1 improves compared to a current flow through between the protrusions 193a adjacent to each other in the circumferential direction of the outer periphery of the effective pixel region RE1.

The distance D₁₁ between the protrusion groups 193 adjacent to each other in the circumferential direction of the outer periphery of the effective pixel region RE1 and the distance D₂₁ between the protrusions 193a adjacent to each other in the circumferential direction of the outer periphery of the effective pixel region RE1 preferably satisfy 1.5×D₂₁≤D₁₁, more preferably 2×D₂₁≤D₁₁, still more preferably 3×D₂₁≤D₁₁, 4×D₂₁≤D₁₁, 5×D₂₃≤D₁₁, or 6×D₂₁≤D₁₁ from the viewpoint of securing a current path in the direction away from the effective pixel region RE1. The distance D₁₁ between the protrusion groups 193 adjacent to each other in the circumferential direction of the outer periphery of the effective pixel region RE1 and the distance D₂₁ between the protrusions 193a adjacent to each other in the circumferential direction of the outer periphery of the effective pixel region RE1 preferably satisfy D₁₁≤10×D₂₁ from the viewpoint of suppressing a decrease in the contact area between the peripheral edge portion of the cathode 123 and the contact electrode 19.

The interval D₂₂ between the protrusions 193a adjacent to each other in the direction away from the effective pixel region RE1 may be the same as or different from the distance D₂₁ between the protrusions 193a adjacent to each other in the circumferential direction of the outer periphery of the effective pixel region RE1. The interval D₂₂ between the protrusions 193a adjacent to each other in the direction away from the effective pixel region RE1 is preferably less than the distance D₁₁ between the protrusion groups 193 adjacent to each other in the circumferential direction of the outer periphery of the effective pixel region RE1. With this configuration, a decrease in the number of the plurality of protrusion groups 193 included in each protrusion group 193 can be suppressed, and a decrease in the contact area between the peripheral edge portion of the cathode 123 and the contact electrode 19 can be suppressed.

### Actions and Effects

In the display device 103 according to the third embodiment, the contact electrode 19 includes the protrusion groups 193 on the first surface. With this configuration, the contact area between the cathode 123 and the contact electrode 19 can be increased. The plurality of protrusion groups 193 is arranged at intervals in the circumferential direction of the outer periphery of the effective pixel region RE1. With this configuration, a current path can be secured between the protrusion groups 193 adjacent to each other in the circumferential direction of the outer periphery of the effective pixel region RE1. It is thus possible for the display device 103 according to the third embodiment to secure a current path in the direction away from the effective pixel region RE1 while increasing the contact area between the cathode 123 and the contact electrode 19.

### 6. Fourth Embodiment

### Configuration of Display Device 104

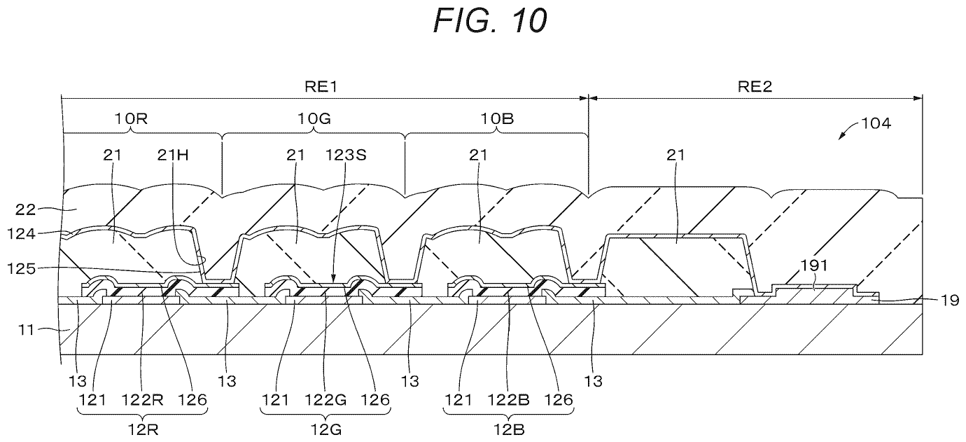

FIG. 10 is a cross-sectional view of a display device 104 according to the fourth embodiment. The display device 104 includes a drive substrate 11, a plurality of light-emitting elements (first light-emitting elements) 12R, a plurality of light-emitting elements (second light-emitting elements) 12G, a plurality of light-emitting elements (third light-emitting elements) 12B, a common electrode 124, a first protective layer 21, a second protective layer 22, and a contact electrode 19. Note that, in the fourth embodiment, portions similar to those of the first embodiment are denoted by the same reference signs, and the description thereof will be omitted. Note that, in the following description, the light-emitting elements 12R, 12G, and 12B are collectively referred to as light-emitting element 12 unless otherwise distinguished. In the fourth embodiment, the common electrode 124 is an example of the first electrode in the claims.

### Light-Emitting Elements 12R, 12G, and 12B

The light-emitting element 12R, the light-emitting element 12G, and the light-emitting element 12B are different in emission color. The light-emitting element 12R can emit red light under the control of the corresponding drive circuit and the like. The light-emitting element 12G can emit green light under the control of the corresponding drive circuit and the like. The light-emitting element 12B can emit blue light under the control of the corresponding drive circuit and the like. The light-emitting element 12 is an organic light emitting diode (OLED) element. The light-emitting element 12R includes a sub-pixel 10R. The light-emitting element 12G includes a sub-pixel 10G. The light-emitting element 12B includes a sub-pixel 10B.

The plurality of light-emitting elements 12 is arranged two-dimensionally on the first surface of the drive substrate 11 in a prescribed arrangement pattern. The prescribed arrangement pattern is as described as the prescribed arrangement pattern of the plurality of sub-pixels 10 in the first embodiment.

The light-emitting element 12R includes an anode 121, an OLED layer 122R, and a cathode 126 in this order on the first surface of the drive substrate 11. The light-emitting element 12G includes an anode 121, an OLED layer 122G, and a cathode 126 in this order on the first surface of the drive substrate 11. The light-emitting element 12B includes an anode 121, an OLED layer 122B, and a cathode 126 in this order on the first surface of the drive substrate 11. In the fourth embodiment, one of the anode 121 or the cathode 126 is an example of the third electrode in the claims, and the other is an example of the fourth electrode in the claims.

### OLED Layers 122R, 122G, 122B

The OLED layer 122R can emit red light. The OLED layer 122G can emit green light. The OLED layer 122B can emit blue light.

The OLED layers 122R, 122G, and 122B are each provided between the anode 121 and the cathode 126. The OLED layer 122R includes an organic light-emitting layer capable of emitting red light (hereinafter, referred to as “red organic light-emitting layer”). The OLED layer 122R includes an organic light-emitting layer capable of emitting green light (hereinafter, referred to as “green organic light-emitting layer”). The OLED layer 122B includes an organic light-emitting layer capable of emitting blue light (hereinafter, referred to as “blue organic light-emitting layer”). In the following description, in a case where the red organic light-emitting layer, the green organic light-emitting layer, and the blue organic light-emitting layer are collectively referred to organic light-emitting layer unless otherwise distinguished.

The OLED layers 122R, 122G, and 112B may each include a laminate including an organic light-emitting layer, and in this case, a layer (for example, an electron injection layer) of the laminate may be an inorganic layer. The OLED layer 122R includes, for example, a hole injection layer, a hole transport layer, a red organic light-emitting layer, an electron transport layer, and an electron injection layer in this order from the anode 121 toward the cathode 126. The OLED layer 122G includes, for example, a hole injection layer, a hole transport layer, a green organic light-emitting layer, an electron transport layer, and an electron injection layer in this order from the anode 121 toward the cathode 126. The OLED layer 122G includes, for example, a hole injection layer, a hole transport layer, a blue organic light-emitting layer, an electron transport layer, and an electron injection layer in this order from the anode 121 toward the cathode 126.

The red organic light-emitting layer can emit red light by recombination of holes injected from the anode 121 and electrons injected from the cathode 126. The green organic light-emitting layer can emit green light on the basis of a principle similar to that of the red organic light-emitting layer. The blue organic light-emitting layer can emit blue light on the basis of a principle similar to that of the red organic light-emitting layer.

### Cathode 126

The cathode 126 is an individual electrode individually provided for each of the plurality of light-emitting elements 12W in the effective pixel region RE1. That is, the anode 121 is separated between the light-emitting elements 12 adjacent to each other in an in-plane direction of the first surface of the drive substrate 11 in the effective pixel region RE1. The cathode 126 is otherwise similar to the cathode 123 in the first embodiment.

### First Protective Layer 21, Second Protective Layer 22

The first protective layer 21 and the second protective layer 22 have transparency to light of each color emitted from the light-emitting elements 12R, 12G, and 12B. The first protective layer 21 and the second protective layer 22 preferably have transparency to visible light. The first protective layer 21 and the second protective layer 22 can protect the plurality of light-emitting elements 12 and the like. For example, the first protective layer 21 and the second protective layer 22 can block the plurality of light-emitting elements 12 from the outside air to suppress moisture ingress into the plurality of light-emitting elements 12 from the external environment.

The first protective layer 21 is provided on the first surface of the drive substrate 11 to cover the plurality of light-emitting elements 12. The first protective layer 21 includes a plurality of contact holes 21H passing through the first protective layer 21 in the thickness direction. Each contact hole 21H may be provided in the light-emitting region of the corresponding light-emitting element 12 in plan view, or may be provided outside the light-emitting region of the light-emitting element 12 in plan view. FIG. 10 illustrates an example where each contact hole 21H is provided outside the light-emitting region of the corresponding light-emitting element 12 in plan view. The second protective layer 22 is provided on the first surface of the common electrode 124.

As materials included in the first protective layer 21 and the second protective layer 22, a material similar to that of the protective layer 14 in the first embodiment can be exemplified. The materials included in the first protective layer 21 and the second protective layer 22 may be the same or different.

### Common Electrode 124

The common electrode 124 is provided on the first surface of the first protective layer 21. The common electrode 124 is an electrode that extends across the light-emitting elements 12 adjacent to each other in the effective pixel region RE1 and is shared by the plurality of light-emitting elements 12 provided in a display region 110A. The common electrode 124 has transparency to each light emitted from the light-emitting elements 12R, 12G, and 12B. The common electrode 124 preferably has transparency to visible light. The common electrode 124 extends from the effective pixel region RE1 to the peripheral region RE2. The second surface of the common electrode 124 has its peripheral edge portion connected to the first surface of the contact electrode 19. The peripheral edge portion of the common electrode 124 may be provided on the first surface of the contact electrode 19 so as to follow the plurality of protrusions 191.

The common electrode 124 is connected to each cathode 126 separated for each sub-pixel 10. Specifically, the common electrode 124 includes a plurality of contacts 125, and each of the plurality of contacts 125 is provided in the corresponding contact hole 21H of the first protective layer 1. With this configuration, each of the plurality of contacts 125 has its tip connected to the first surface of the corresponding cathode 126 separated for each sub-pixel 10.

### Actions and Effects

In the fourth embodiment, the common electrode 124 has its peripheral edge portion connected to the contact electrode 19. The contact electrode 19 includes the plurality of protrusions 191 described in the first embodiment on the first surface. It is thus possible to secure a current path in the direction away from the effective pixel region RE1 while increasing the contact area between the peripheral edge portion of the common electrode 124 and the contact electrode 19.

### 7. Fifth Embodiment

### Configuration of Display Device 105

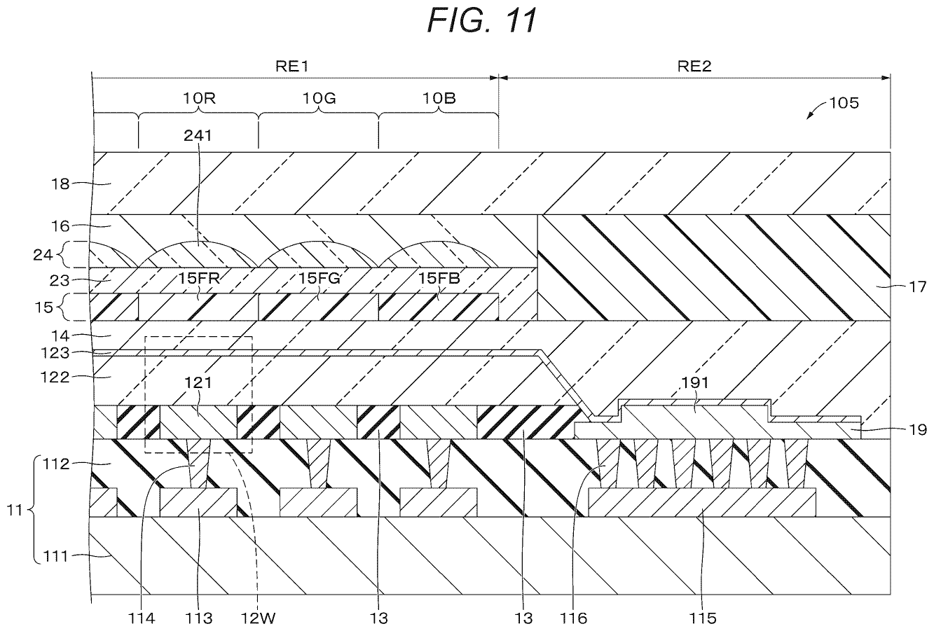

FIG. 11 is a cross-sectional view of a display device 105 according to the fifth embodiment. The display device 105 is different from the display device 101 (see FIG. 3) according to the first embodiment in further including a planarization layer 23 and a lens array 24.

### Planarization Layer 23

The planarization layer 23 is provided on the first surface of the color filter 15. The planarization layer 23 has a flat first surface. The planarization layer 23 can fill irregularities on the first surface of the color filter 15 to form the flat first surface above the color filter 15. The planarization layer 23 includes, for example, an inorganic material or a polymer resin. As the inorganic material, a material similar to the inorganic material of the protective layer 14 can be exemplified. As the polymer resin, a material similar to the polymer resin of the protective layer 14 can be exemplified.

### Lens Array 24

The lens array 24 is provided on the first surface of the planarization layer 23. The lens array 24 includes a plurality of lenses 241. Each lens 241 can condense the light emitted upward from the corresponding light-emitting element 12W in the front direction. The plurality of lenses 241 is so-called on chip microlenses (OCL) and is arranged two-dimensionally on the first surface of the planarization layer 23 in a prescribed arrangement pattern.

A single lens 241 may be provided above each light-emitting element 12W, or two or more lenses 241 may be provided above each light-emitting element 12W. FIG. 11 illustrates an example where a single lens 241 is provided above each light-emitting element 12W. The lens 241 may have a curved emission surface from which the light incident from the light-emitting element 12W is emitted. The curved surface may be a convex surface that curves in a direction away from the light-emitting element 12W or a concave surface that curves in a direction approaching the light-emitting element 12W. Examples of the curved surface include, but are not limited to, an approximately parabolic shape, an approximately hemispherical shape, an approximately semielliptical shape, and the like.

The lens array 24 includes, for example, an inorganic material or a polymer resin with transparency to visible light. The inorganic material includes, for example, silicon oxide (SiOₓ). Examples of the polymer resin include an ultraviolet curable resin.

### Filling Resin Layer 16

In the fifth embodiment, the filling resin layer 16 covers the lens array 24. The filling resin layer 16 is different in refractive index from the lens array 24. The filling resin layer 16 may be higher or lower in refractive index than the lens array 24. In a case where the lens 241 has a convex emission surface, the filling resin layer 16 is preferably lower in refractive index than the lens array 24 from the viewpoint of improving front luminance. In a case where the lens 241 has a concave emission surface, the filling resin layer 16 is preferably higher in refractive index than the lens array 24 from the viewpoint of improving front luminance.

### Actions and Effects

In the fifth embodiment, the lens array 24 is provided above the plurality of light-emitting elements 12. With this configuration, the light emitted upward from the light-emitting elements 12W can be condensed in the front direction by the lens array 24. It is thus possible to improve the front luminance of the display device 105.

### 8. Modifications

### Modification 1

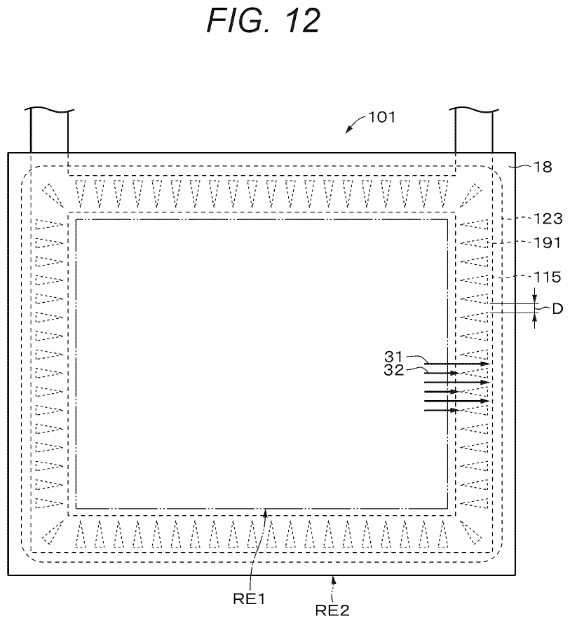

The display device 101 according to the first embodiment may include a plurality of protrusions 191 having the following configuration. That is, as illustrated in FIG. 12, a distance D between the protrusions 191 adjacent to each other on the inner peripheral side of the peripheral region RE2 may be greater than a distance D between the protrusions 191 adjacent to each other on the outer peripheral side of the peripheral region RE2. The distance D between the protrusions 191 adjacent to each other may gradually increase from the outer periphery of the peripheral region RE2 toward the inner periphery of the peripheral region RE2.

Each protrusion 191 may have a side surface inclined relative to the outer periphery of the effective pixel region RE1 in plan view. The protrusion 191 may gradually decrease in width from the outer periphery of the peripheral region RE2 toward the inner periphery of the peripheral region RE2 in plan view. Here, the width of the protrusion 191 indicates a dimension of the protrusion 191 in a direction perpendicular to the extending direction of the protrusion 191. The protrusion 191 may have, for example, a triangular shape or a trapezoidal shape in plan view, or may have another type of shape. The triangular shape may be, for example, an isosceles triangle. In a case where the protrusion 191 has a triangular shape in plan view, one vertex of the triangular shape may be located on the inner peripheral side of the peripheral region RE2, and the remaining two vertices may be located on the outer peripheral side of the peripheral region RE2. In a case where the protrusion 191 has a trapezoidal shape in plan view, the upper base of the trapezoidal shape may be located on the inner peripheral side of the peripheral region RE2, and the lower base may be located on the outer peripheral side of the peripheral region RE2.

In the display device 101 according to Modification 1, the distance D between the protrusions 191 adjacent to each other on the inner peripheral side of the peripheral region RE2 is greater than the distance D between the protrusions 191 adjacent to each other on the outer peripheral side of the peripheral region RE2. With this configuration, a current flowing from the effective pixel region RE1 toward the peripheral region RE2 becomes easy to flow into between the protrusions 191 adjacent to each other in the circumferential direction of the outer periphery of the effective pixel region RE1. Thus, a good current path (carrier path) can be formed between the protrusions 191 adjacent to each other in the circumferential direction of the outer periphery of the effective pixel region RE1.

The display device 102 according to the second embodiment may include a plurality of protrusions 192a having the same configuration as the plurality of protrusions 191 described in Modification 1. The display devices 104 and 105 according to the fourth and fifth embodiments may include the plurality of protrusions 191 described in Modification 1.

### Modification 2

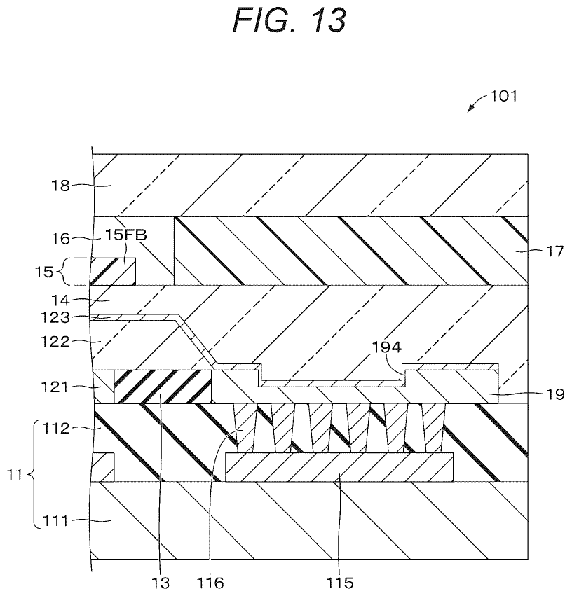

In the first, fourth, and fifth embodiments, the example where the contact electrode 19 includes the plurality of protrusions 191 as the plurality of structures on the first surface has been described, but, as illustrated in FIG. 13, the contact electrode 19 may include a plurality of recesses 194 as the plurality of structures on the first surface, or may include a plurality of protrusions 191 and a plurality of recesses 194 as the plurality of structures. The recess 194 is a structure obtained by inverting the protrusion 191.

In the second embodiment, the example where the contact electrode 19 includes the plurality of protrusion groups 192 as the plurality of structure groups on the first surface has been described, but the contact electrode 19 may include a plurality of recess groups as the plurality of structure groups on the first surface, or may include a plurality of protrusion groups 192 and a plurality of recess groups as the plurality of structure groups on the first surface. The recess group is a structure group obtained by inverting the protrusion group 192.

In the second embodiment, the example where the structure group includes the plurality of first protrusions 192a and the plurality of second protrusions 192b has been described, but the structure group may include a plurality of first recesses instead of the plurality of first protrusions 192a, or include a plurality of second recesses instead of the plurality of second protrusions 192b. The first recess is a structure obtained by inverting the first protrusion 192a, and the second recess is a structure obtained by inverting the second protrusion 192b.

In the second embodiment, the example where the structure group includes the plurality of first protrusions 192a as the plurality of first structures has been described, but the structure group may include a plurality of first protrusions 192a and a plurality of first recesses as the plurality of first structures. The first recess is a structure obtained by inverting the first protrusion 192a as described above.

In the second embodiment, the example where the structure group includes the plurality of second protrusions 192b as the plurality of second structures has been described, but the structure group may include a plurality of second protrusions 192b and a plurality of second recesses as the plurality of second structures. The second recess is a structure obtained by inverting the second protrusion 192b as described above.

In the third embodiment, the example where the contact electrode 19 includes the plurality of protrusion groups 193 as the plurality of structure groups on the first surface has been described, but the contact electrode 19 may include a plurality of recess groups as the plurality of structure groups on the first surface, or may include a plurality of protrusion groups 193 and a plurality of recess groups as the plurality of structure groups on the first surface. The recess group is a structure group obtained by inverting the protrusion group 193. The depths of the plurality of recesses included in the recess group may be approximately the same or different.

In the third embodiment, the example where the structure group includes the plurality of protrusions 193a has been described, but the structure group may include a plurality of protrusions 193a and a plurality of recesses. The recess is a structure obtained by inverting the protrusion 193a.

### Modification 3

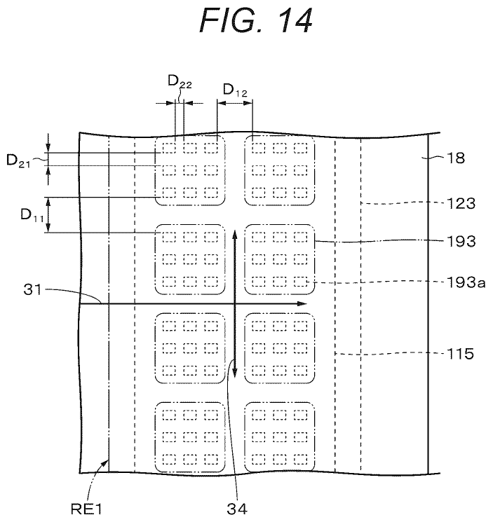

In the third embodiment, the example where the plurality of protrusion groups 193 is arranged at intervals in the circumferential direction of the outer periphery of the effective pixel region RE1 has been described, but, as illustrated in FIG. 14, the plurality of protrusion groups 193 may be arranged two-dimensionally. Specifically, the plurality of protrusion groups 193 may be arranged at intervals in the circumferential direction of the outer periphery of the effective pixel region RE1 and be arranged at intervals in the direction away from the effective pixel region RE1. A distance D₁₁ between the protrusion groups 193 adjacent to each other in the circumferential direction of the outer periphery of the effective pixel region RE1 may be constant or variable. A distance D₁₂ between the protrusion groups 193 adjacent to each other in the direction away from the effective pixel region RE1 may be constant or variable.

The distance D₁₂ between the protrusion groups 193 adjacent to each other in the direction away from the effective pixel region RE1 is preferably greater than a distance D₂₂ between the protrusions 193a adjacent to each other in the direction away from the effective pixel region RE1. With this configuration, a current flow through between the protrusion groups 193 adjacent to each other in the direction away from the effective pixel region RE1 improves compared to a current flow through between the protrusions 193a adjacent to each other in the direction away from the effective pixel region RE1. In FIG. 14, an arrow 34 represents an image of a current path formed between the protrusion groups 193 adjacent to each other in the direction away from the effective pixel region RE1.

The distance D₁₂ between the protrusion groups 193 adjacent to each other in the direction away from the effective pixel region RE1 and the distance D₂₂ between the protrusions 193a adjacent to each other in the direction away from the effective pixel region RE1 preferably satisfy 1.5×D₂₂≤D₁₂, more preferably 2×D₂₂≤D₁₂, still more preferably 3×D₂₂≤D₁₂, 4×D₂₂≤D₁₂, 5×D₂₂≤D₁₂, or 6×D₂₂≤D₁₂ from the viewpoint of securing a current path in the direction away from the effective pixel region RE1. The distance D₁₂ between the protrusion groups 193 adjacent to each other in the direction away from the effective pixel region RE1 and the distance D₂₂ between the protrusions 193a adjacent to each other in the direction away from the effective pixel region RE1 preferably satisfy D₁₂≤10×D₂₂ from the viewpoint of suppressing a decrease in the contact area between the peripheral edge portion of the cathode 123 and the contact electrode 19.

### Modification 4

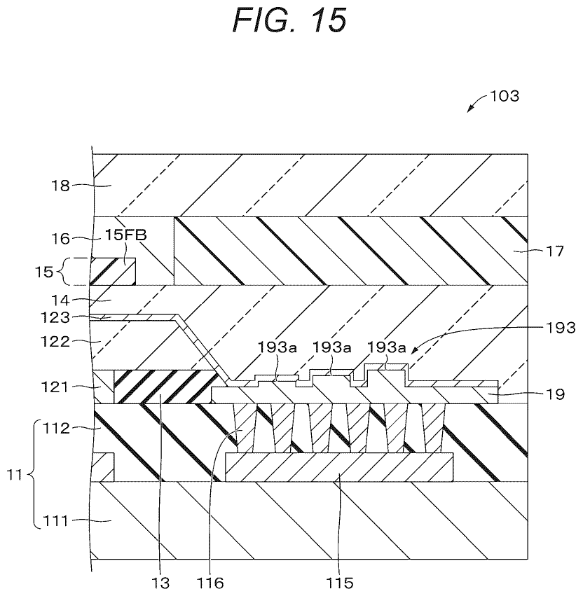

In the third embodiment, as illustrated in FIG. 15, the plurality of protrusions 193a provided on the inner peripheral side of the peripheral region RE2 may be less in height than the plurality of protrusions 193a provided on the outer peripheral side of the peripheral region RE2. More specifically, for example, the plurality of protrusions 193a may gradually decrease in height from the outer periphery of the peripheral region RE2 toward the inner periphery of the peripheral region RE2. In this case, it is possible to prevent the peripheral edge portion of the cathode 123 from being cut off by the steps of the plurality of protrusions 193a or to prevent the peripheral edge portion of the cathode 123 from being thinned by the steps of the plurality of protrusions 193a. Thus, it becomes easier to secure a current path (carrier path) in the direction away from the effective pixel region RE1.

In the second embodiment, the heights of the plurality of first protrusions 192a and the plurality of second protrusions 192b may vary in a manner similar to the plurality of protrusions 193a described in Modification 4.

As described in Modification 2, in a case where the contact electrode 19 include a plurality of recess groups as a plurality of structure groups on the first surface, the plurality of recesses provided on the inner peripheral side of the peripheral region RE2 may be less in depth than the plurality of recesses provided on the outer peripheral side of the peripheral region RE2. More specifically, for example, the plurality of recesses may gradually decrease in depth from the outer periphery of the peripheral region RE2 toward the inner periphery of the peripheral region RE2. In this case, it is possible to prevent the peripheral edge portion of the cathode 123 from being cut off by the steps of the plurality of recesses or to prevent the electrode at the peripheral edge portion of the cathode 123 from being thinned by the steps of the plurality of recesses. Thus, it becomes easier to secure a current path (carrier path) in the direction away from the effective pixel region RE1.

### Modification 5

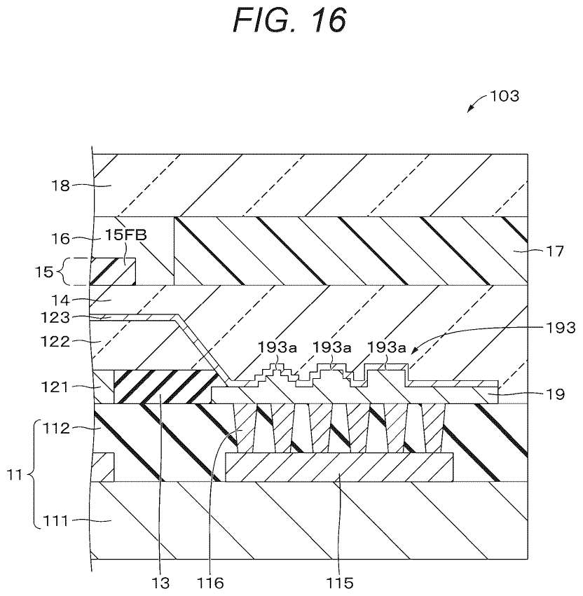

In the third embodiment, the plurality of protrusions 193a may each have at least one step as illustrated in FIG. 16. The heights of the plurality of protrusions 193a may be the same or different. The number of steps of the plurality of protrusions 193a provided on the inner peripheral side of the peripheral region RE2 may be greater than the number of steps of the plurality of protrusions 193a provided on the outer peripheral side of the peripheral region RE2. With this configuration, the steps of the plurality of protrusions 193a provided on the inner peripheral side of the peripheral region RE2 can be made smaller than the steps of the plurality of protrusions 193a provided on the outer peripheral side of the peripheral region RE2. It is therefore possible to prevent the peripheral edge portion of the cathode 123 from being cut off by the steps of the plurality of protrusions 193a or to prevent the peripheral edge portion of the cathode 123 from being thinned by the steps of the plurality of protrusions 193a. Thus, it becomes easier to secure a current path (carrier path) in the direction away from the effective pixel region RE1.

The number of steps of the plurality of protrusions 193a may gradually increase from the outer periphery of the peripheral region RE2 toward the inner periphery of the peripheral region RE2. With this configuration, the steps of the plurality of protrusions 193a can gradually decrease in height from the outer periphery of the peripheral region RE2 toward the inner periphery of the peripheral region RE2.

### Modification 6

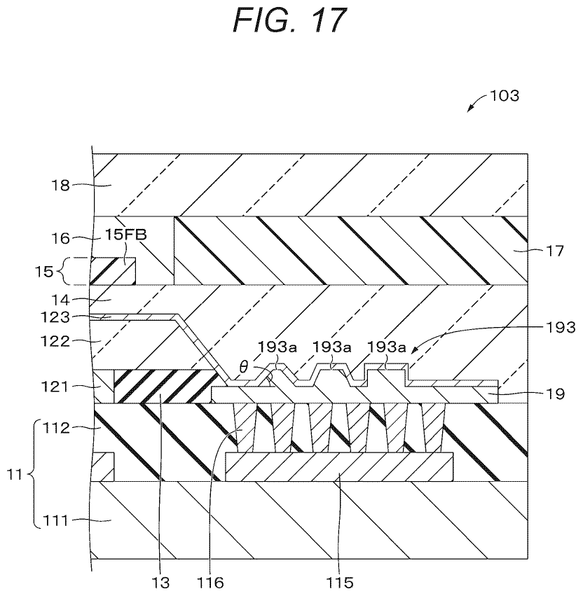

In the third embodiment, inclination angles θ of the side surfaces of the plurality of protrusions 193a may be different as illustrated in FIG. 17. The inclination angle θ of the side surfaces of the plurality of protrusions 193a provided on the inner peripheral side of the peripheral region RE2 may be less than the inclination angle θ of the side surfaces of the plurality of protrusions 193a provided on the outer peripheral side of the peripheral region RE2. More specifically, for example, the inclination angle θ of the plurality of protrusions 193a may gradually decrease from the outer periphery of the peripheral region RE2 toward the inner periphery of the peripheral region RE2. In this case, it is possible to prevent the peripheral edge portion of the cathode 123 from being cut off by the side surfaces of the plurality of protrusions 193a or to prevent the peripheral edge portion of the cathode 123 from being thinned by the side surfaces of the plurality of protrusions 193a. Thus, it becomes easier to secure a current path (carrier path) in the direction away from the effective pixel region RE1.

As described in Modification 2, in a case where the contact electrode 19 includes a plurality of recess groups as a plurality of structure groups on the first surface, the inclination angles θ of the side surfaces of the plurality of recesses may be different. The inclination angle θ of the side surfaces of the plurality of recesses provided on the inner peripheral side of the peripheral region RE2 may be less than the inclination angle θ of the side surfaces of the plurality of recesses provided on the outer peripheral side of the peripheral region RE2. More specifically, for example, the inclination angle θ of the plurality of recesses may gradually decrease from the outer periphery of the peripheral region RE2 toward the inner periphery of the peripheral region RE2.

### Modification 7

In the first to fifth embodiments, the example where the light-emitting element is an OLED element has been described, but the light-emitting element is not limited to the example and may be, for example, a self-luminous light-emitting element such as a light emitting diode (LED), an inorganic electro-luminescence (IEL) element, or a semiconductor laser element. The display device may include two or more types of light-emitting elements.

### Modification 8

In the first to fifth embodiments, the example where the light-emitting device is a display device have been described, but the light-emitting device is not limited to a display device and may be a lighting device or the like.

### Modification 9

In the fourth embodiment, the example where the display device 101 according to the first embodiment includes the plurality of light-emitting elements 12R, 12G, and 12B instead of the plurality of light-emitting elements 12W and the color filter 15 has been described. The present disclosure, however, is not limited to this example, and for example, the display devices 102, 103, and 104 according to the second, third, and fourth embodiments may each include the plurality of light-emitting elements 12R, 12G, and 12B instead of the plurality of light-emitting elements 12W and the color filter 15.

### Modification 10

In the first, second, third, and fifth embodiments, the example where the anode 121 and the cathode 123 are an individual electrode (second electrode) and a common electrode (first electrode), respectively, and the peripheral edge portion of the cathode 123 is connected to the contact electrode 19 has been described, but the anode 121 and the cathode 123 may be the common electrode (first electrode) and the individual electrode (second electrode), respectively, and the peripheral edge portion of the anode 121 may be connected to the contact electrode 19. In this case, the positions of the anode 121 and the cathode 123 may be interchanged.

In the fourth embodiment, the example where the anode 121 and the cathode 126 are an individual electrode (third electrode) and an individual electrode (fourth electrode), respectively, and the plurality of cathodes 126 is connected to the common electrode 124 has been described, but the anode 121 and the cathode 126 are the individual electrode (third electrode) and the individual electrode (fourth electrode), respectively, and the plurality of anodes 121 may be connected to the common electrode 124. In this case, the positions of the anode 121 and the cathode 126 may be interchanged.

### Modification 11

In the second embodiment, the example where the first protrusion 192a is similar to the protrusion 191 in the first embodiment has been described, but the first protrusion 192a need not be similar to the protrusion 191 in the first embodiment. For example, the first protrusion 192a may have a dot shape in plan view. In this case, the plurality of first protrusions 192a may be arranged one-dimensionally or two-dimensionally. In a case of the one-dimensional arrangement, the plurality of first protrusions 192a may be arranged at intervals in the circumferential direction of the outer periphery of the effective pixel region RE1. In a case of the two-dimensional arrangement, the plurality of first protrusions 192a may be arranged two-dimensionally in a manner similar to the plurality of protrusions 193a in the third embodiment.

### Modification 12

In the fourth embodiment, the display device 104 may further include the filling resin layer 16, the seal portion 17, and the cover glass 18. In this case, the filling resin layer 16 and the seal portion 17 may be provided on the first surface of the second protective layer 22.

### Modification 13

In the first, second, third, and fifth embodiments, the example where the color filter 15 is provided has been described, but a quantum dot layer may be provided instead of the color filter 15, or a quantum dot layer may be provided together with the color filter 15. The quantum dot layer includes quantum dots (semiconductor particles), and can convert colors of light emitted from a plurality of light-emitting elements. As the plurality of light-emitting elements, a plurality of light-emitting elements 20B may be provided instead of a plurality of light-emitting elements 20W.

### Other Modifications

Although the first to fifth embodiments of the present disclosure and modifications thereof have been specifically described above, the present disclosure is not limited to the above-described first to fifth embodiments and modifications thereof, and various modifications based on the technical idea of the present disclosure are possible.

For example, the configurations, methods, processes, shapes, materials, numerical values, and the like mentioned in the above-described first to fifth embodiments and modifications thereof are merely examples, and different configurations, methods, processes, shapes, materials, numerical values, and the like may be used as necessary.

For example, the configurations, methods, processes, shapes, materials, numerical values, and the like of the above-described first to fifth embodiments and modifications thereof can be combined with each other without departing from the gist of the present disclosure.

For example, the materials exemplified in the above-described first to fifth embodiments and modifications thereof can be used alone or in combination of two or more unless otherwise specified.

Furthermore, the present disclosure may also employ the following configurations.
(1)

A light-emitting device including:
a plurality of light-emitting elements in a light-emitting region;
a contact electrode provided in a peripheral region located around the light-emitting region; and
a first electrode extending from the light-emitting region to the peripheral region and connected to the contact electrode, in which
the contact electrode includes a plurality of first structures at a portion where the first electrode is connected, and
a plurality of the first structures extends in a direction away from the light-emitting region.
(2)

The light-emitting device according to (1) or (2), in which
a plurality of the first structures includes at least one of a plurality of first recesses or a plurality of first protrusions.
(3)

The light-emitting device according to (1) or (2), in which
the contact electrode has a loop shape surrounding the light-emitting region.
(4)

The light-emitting device according to any one of (1) to (3), in which
the direction away from the light-emitting region includes a direction perpendicular to an outer periphery of the light-emitting region or a direction oblique to the outer periphery of the light-emitting region.
(5)

The light-emitting device according to any one of (1) to (4), in which
a plurality of the first structures is arranged in a circumferential direction of an outer periphery of the light-emitting region, and
a distance between the first structures adjacent to each other on an inner peripheral side of the peripheral region is greater than a distance between the first structures adjacent to each other on an outer peripheral side of the peripheral region.
(6)

The light-emitting device according to any one of (1) to (5), in which
the contact electrode further includes a plurality of second structures at the portion where the first electrode is connected,
a plurality of the second structures extends in a direction approximately perpendicular to an extending direction of the first structures, and
a plurality of the first structures is provided closer to the light-emitting region than a plurality of the second structures.
(7)

The light-emitting device according to any one of (1) to (6), in which
the light-emitting region includes an effective pixel region, and
the first electrode includes a cathode.
(8)

The light-emitting device according to any one of (1) to (7), further including:
a plurality of second electrodes provided in the light-emitting region; and
an organic light-emitting layer provided between a plurality of the second electrodes and the first electrode.
(9)

The light-emitting device according to any one of (1) to (7), further including:
a plurality of third electrodes provided in the light-emitting region;
a plurality of fourth electrodes provided in the light-emitting region; and
a plurality of organic light-emitting layers provided in the light-emitting region, in which
each of the organic light-emitting layers is provided between a corresponding one of the third electrodes and a corresponding one of the fourth electrodes, and
the first electrode is connected to a plurality of the fourth electrodes.
(10)

A light-emitting device including:
a plurality of light-emitting elements in a light-emitting region;
a contact electrode provided in a peripheral region located around the light-emitting region; and
a first electrode extending from the light-emitting region to the peripheral region and connected to the contact electrode, in which
the contact electrode includes a plurality of structure groups at a portion where the first electrode is connected,
a plurality of the structure groups is arranged at least in a circumferential direction of an outer periphery of the light-emitting region,
each of the structure groups includes a plurality of structures, and
the structure groups adjacent to each other in the circumferential direction are separated from each other.
(11)

The light-emitting device according to (10), in which
a plurality of the structures includes at least one of a plurality of recesses or a plurality of protrusions.
(12)

The light-emitting device according to (10) or (11), in which
a distance between the structure groups adjacent to each other in the circumferential direction is greater than a distance between the structures adjacent to each other.
(13)

The light-emitting device according to (10) or (11), in which
a plurality of the structures is arranged two-dimensionally in the circumferential direction and a direction approximately perpendicular to the circumferential direction, and
a distance between the structure groups adjacent to each other in the circumferential direction is greater than a distance between the structures adjacent to each other in the circumferential direction.
(14)

The light-emitting device according to (10) or (11), in which
a plurality of the structure groups is arranged two-dimensionally in the circumferential direction and a direction approximately perpendicular to the circumferential direction, and
the structure groups adjacent to each other in the direction approximately perpendicular to the circumferential direction are separated from each other.
(15)

The light-emitting device according to (14), in which
a plurality of the structures is arranged two-dimensionally in the circumferential direction and the direction approximately perpendicular to the circumferential direction,
a distance between the structure groups adjacent to each other in the circumferential direction is greater than a distance between the structures adjacent to each other in the circumferential direction, and
a distance between the structure groups adjacent to each other in the direction approximately perpendicular to the circumferential direction is greater than a distance between the structures adjacent to each other in the direction approximately perpendicular to the circumferential direction.
(16)

The light-emitting device according to (11), in which
a plurality of the structures is arranged two-dimensionally,
a plurality of the recesses becomes shallower from an outer periphery toward an inner periphery of the peripheral region, and
a plurality of the protrusions becomes lower from the outer periphery toward the inner periphery of the peripheral region.
(17)

The light-emitting device according to any one of (10) to (15), in which
a plurality of the structures is arranged two-dimensionally,
a plurality of the structures has at least one step, and
a number of the steps of a plurality of the structures increases from an outer periphery toward an inner periphery of the peripheral region.
(18)

The light-emitting device according to any one of (10) to (15), in which
a plurality of the structures is arranged two-dimensionally, and
inclination angles of side surfaces of a plurality of the structures decrease from an outer periphery toward an inner periphery of the peripheral region.
(19)

The light-emitting device according to any one of (10) to (18), in which
a plurality of the structures has a dot shape in plan view.
(20)

Electronic equipment including the light-emitting device according to any one of (1) to (19).

### 9. Relationship Among Normal Lines Passing Through Centers of Light-Emitting Unit, Lens Member, and Wavelength Selection Unit

Hereinafter, a relationship among a normal line LN passing through a center of a light-emitting unit, a normal line LN′ passing through a center of a lens member, and a normal line LN″ passing through a center of a wavelength selection unit will be described. Here, the light-emitting unit is, for example, the light-emitting element 12W, the light-emitting element 12R, the light-emitting element 12G, or the light-emitting element 12B. The lens member is, for example, the lens 241 of the lens array 24. The wavelength selection unit is, for example, the filter portion 15F.

Note that the size of the wavelength selection unit may be changed as appropriate in accordance with light emitted from the light-emitting unit, or, in a case where a light-absorbing unit (for example, a black matrix unit) is provided between the wavelength selection units of the adjacent light-emitting units, the size of the light-absorbing unit may be changed as appropriate in accordance with light emitted from the light-emitting unit. Furthermore, the size of the wavelength selection unit may be changed as appropriate in accordance with a distance (offset amount) d₀ between the normal line passing through the center of the light-emitting unit and the normal line passing through the center of the wavelength selection unit. The planar shape of the wavelength selection unit may be the same as, similar to, or different from the planar shape of the lens member.

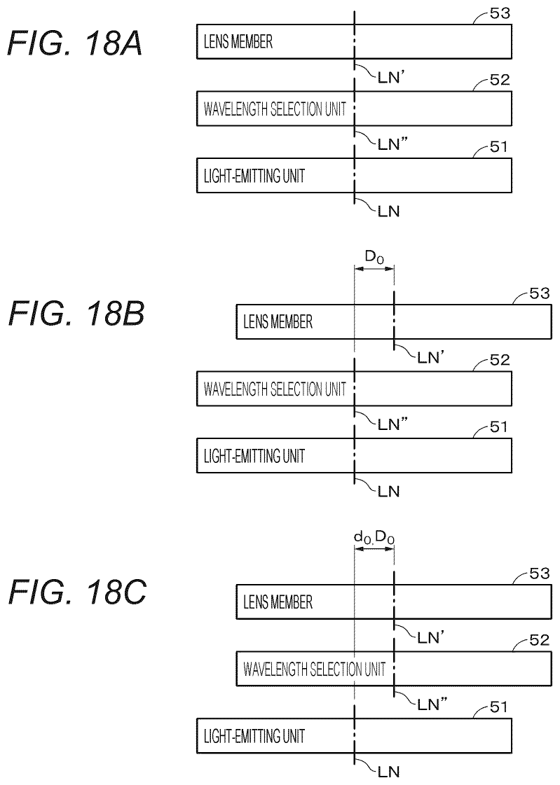

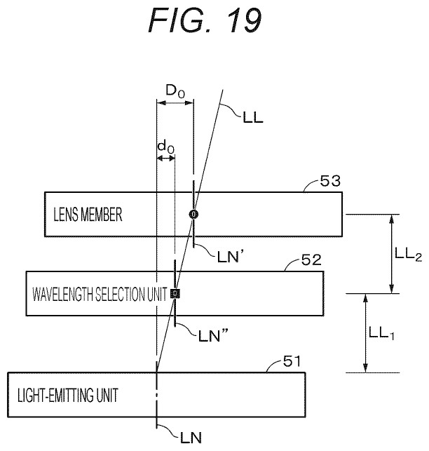

Hereinafter, with reference to FIGS. 18A, 18B, 18C, and 19, a relationship among the normal lines passing through the center of each unit in a case where a light-emitting unit 51, a wavelength selection unit 52, and a lens member 53 are arranged in this order will be described.

As illustrated in FIG. 18A, the normal line LN passing through the center of the light-emitting unit 51, the normal line LN″ passing through the center of the wavelength selection unit 52, and the normal line LN′ passing through the center of the lens member 53 may coincide with each other. That is, D₀=0 and d₀=0 may be satisfied. Here, D₀ represents the distance (offset amount) between the normal line LN passing through the center of the light-emitting unit 51 and the normal line LN′ passing through the center of the lens member 53, and do represents the distance (offset amount) between the normal line LN passing through the center of the light-emitting unit 51 and the normal line LN″ passing through the center of the wavelength selection unit 52.

As illustrated in FIG. 18B, the normal line LN passing through the center of the light-emitting unit 51 and the normal line LN″ passing through the center of the wavelength selection unit 52 coincide with each other, but the normal line LN passing through the center of the light-emitting unit 51 and the normal line LN″ passing through the center of the wavelength selection unit 52 need not coincide with the normal line LN′ passing through the center of the lens member 53. That is, D₀>0 and d₀=0 may be satisfied.

As illustrated in FIG. 18C, the normal line LN passing through the center of the light-emitting unit 51 need not coincide with the normal line LN″ passing through the center of the wavelength selection unit 52 or the normal line LN′ passing through the center of the lens member 53, and the normal line LN″ passing through the center of the wavelength selection unit 52 may coincide with the normal line LN′ passing through the center of the lens member 53. That is, D₀>0, d₀>0, and D₀=d₀ may be satisfied.

As illustrated in FIG. 19, the normal line LN passing through the center of the light-emitting unit 51, the normal line LN″ passing through the center of the wavelength selection unit 52, and the normal line LN′ passing through the center of the lens member 53 need not coincide with each other. That is, D₀>0, d₀>0, and D₀≠d₀ may be satisfied. Here, the center of the wavelength selection unit 52 (position indicated by a black square in FIG. 19) is preferably located on a straight line LL connecting the center of the light-emitting unit 51 and the center of the lens member 53 (position indicated by a black circle in FIG. 19). Specifically, with the distance in the thickness direction (vertical direction in FIG. 19) between the center of the light-emitting unit 51 and the center of the wavelength selection unit 52 denoted as LL₁, and the distance in the thickness direction between the center of the wavelength selection unit 52 and the center of the lens member 53 denoted as LL₂, it is preferable that
D₀>d₀>0
be satisfied, and with manufacturing variations being taken into consideration,
d₀: D₀=LL₁: (LL₁+LL₂)
be satisfied.

Here, the thickness direction indicates the thickness direction of the light-emitting unit 51, the wavelength selection unit 52, and the lens member 53.

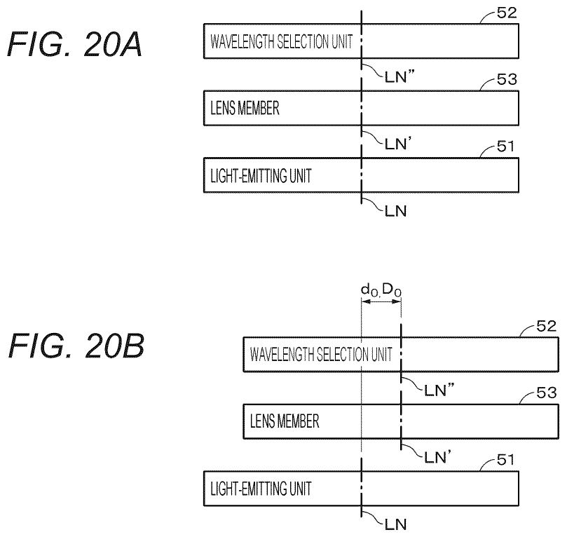

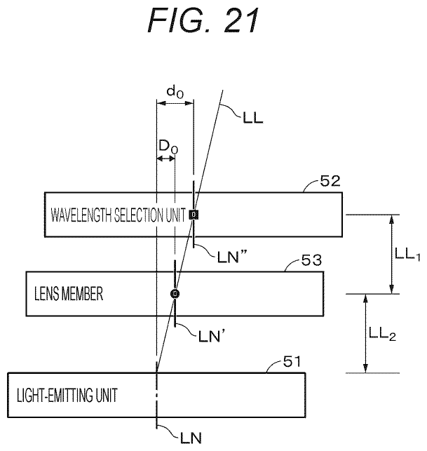

Hereinafter, with reference to FIGS. 20A, 20B, and 21, a relationship among the normal lines passing through the center of each unit in a case where the light-emitting unit 51, the lens member 53, and the wavelength selection unit 52 are arranged in this order will be described.

As illustrated in FIG. 20A, the normal line LN passing through the center of the light-emitting unit 51, the normal line LN″ passing through the center of the wavelength selection unit 52, and the normal line LN′ passing through the center of the lens member 53 may coincide with each other. That is, D₀>0 and d₀=0 may be satisfied.

As illustrated in FIG. 20B, the normal line LN passing through the center of the light-emitting unit 51 need not coincide with the normal line LN″ passing through the center of the wavelength selection unit 52 or the normal line LN′ passing through the center of the lens member 53, and the normal line LN″ passing through the center of the wavelength selection unit 52 may coincide with the normal line LN′ passing through the center of the lens member 53. That is, D₀>0, d₀>0, and D₀=d₀ may be satisfied.

As illustrated in FIG. 21, the normal line LN passing through the center of the light-emitting unit 51, the normal line LN″ passing through the center of the wavelength selection unit 52, and the normal line LN′ passing through the center of the lens member 53 need not coincide with each other. Here, the center of the lens member 53 (the position indicated by a black circle in FIG. 21) is preferably located on a straight line LL connecting the center of the light-emitting unit 51 and the center of the wavelength selection unit 52 (position indicated by a black square in FIG. 21). Specifically, with the distance in the thickness direction (vertical direction in FIG. 21) between the center of the light-emitting unit 51 and the center of the lens member 53 denoted as LL₂, and the distance in the thickness direction between the center of the lens member 53 and the center of the wavelength selection unit 52 denoted as LL₁, it is preferable that
d₀>D₀>0
be satisfied, and, with manufacturing variations being taken into consideration,
D₀: d₀=LL₂: (LL₁+LL₂)
be satisfied.

Here, the thickness direction indicates the thickness direction of the light-emitting unit 51, the wavelength selection unit 52, and the lens member 53.

### 10. Example of Resonator Structure

The pixel used in the display device according to the present disclosure described above may have a resonator structure that causes resonance of light generated by the light-emitting element. Hereinafter, the resonator structure will be described with reference to the drawings. Furthermore, in the following description, the first surface of each layer may be referred to as upper surface.

### Resonator Structure: First Example

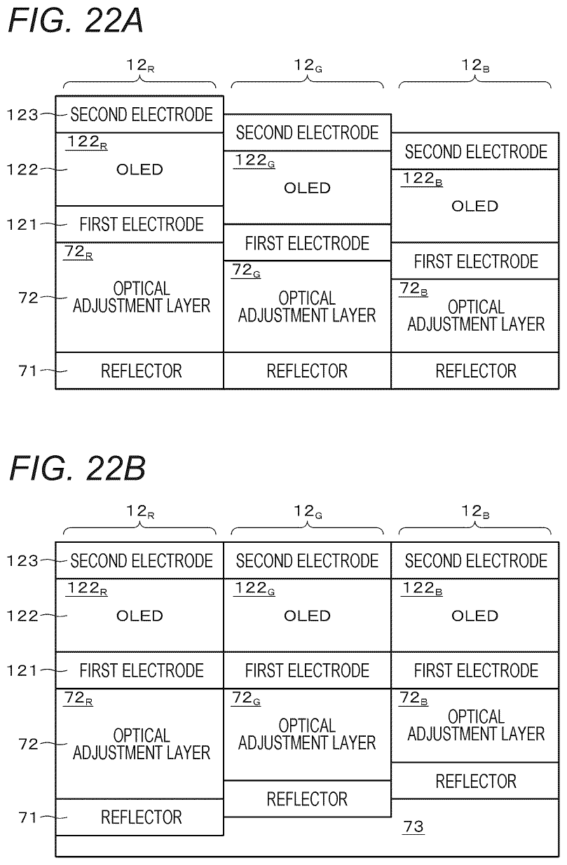

FIG. 22A is a schematic cross-sectional view for describing a first example of the resonator structure. In the following description, in a case where the light-emitting elements provided corresponding to the sub-pixels 10R, 10G, and 10B may be collectively referred to as light-emitting element 12 unless otherwise distinguished. In a case where the light-emitting elements provided corresponding to the sub-pixels 10R, 10G, and 10B are distinguished, they may be referred to as light-emitting elements 12_{R}, 12_{G}, and 12_{B}. Portions of the OLED layer 122 corresponding to the sub-pixels 10R, 10G, and 10B may be referred to as OLED layer 122_{R}, OLED layer 122_{G}, and OLED layer 122_{B}, respectively. The anode 121 and the cathode 123 may be referred to as first electrode 121 and second electrode 123, respectively. The light-emitting element may be the light-emitting element 12W in the first, second, third, and fifth embodiments, or may be the light-emitting elements 12R, 12G, and 12B in the fourth embodiment.

In the first example, the first electrode 121 is formed with a common film thickness in each light-emitting element 12. This similarly applies to the second electrode 123.

A reflector 71 is arranged below the first electrode 121 of the light-emitting element 12 with an optical adjustment layer 72 interposed therebetween. The resonator structure that causes resonance of light generated by the OLED layer 122 is formed between the reflector 71 and the second electrode 123. In the following description, the optical adjustment layers 72 provided corresponding to the sub-pixels 10R, 10G, and 10B are referred to as optical adjustment layers 72_{R}, 72_{G}, and 72_{B}, respectively.

The reflector 71 is formed with a common film thickness in each light-emitting element 12. The film thickness of the optical adjustment layer 72 differs in a manner that depends on the color to be displayed by the pixel. Since the optical adjustment layers 72_{R}, 72_{G}, and 72_{B} have different film thicknesses, it is possible to set an optical distance that causes optimum resonance at the wavelength of light corresponding to the color to be displayed.

In the example illustrated in FIG. 22A, the upper surfaces of the reflectors 71 in the light-emitting elements 12_{R}, 12_{G}, and 12_{B} are flush with each other. As described above, since the film thickness of the optical adjustment layer 72 differs in a manner that depends on the color to be displayed by the pixel, the position of the upper surface of the second electrode 123 differs in a manner that depends on the types of the light-emitting elements 12_{R}, 12_{G}, and 12_{B}.

The reflector 71 can be formed with, for example, a metal such as aluminum (Al), silver (Ag), or copper (Cu), or an alloy primarily containing these metals.

The optical adjustment layer 72 can include an inorganic insulating material such as silicon nitride (SiNₓ), silicon oxide (SiOₓ), or silicon oxynitride (SiOₓN_{y}), or an organic resin material such as an acrylic resin or a polyimide resin. The optical adjustment layer 72 may be a single layer, or may be a multilayer film of a plurality of the materials described above. Furthermore, the number of layers may differ in a manner that depends on the type of the light-emitting element 12.

The first electrode 121 can be formed with a transparent conductive material such as indium tin oxide (ITO), indium zinc oxide (IZO), or zinc oxide (ZnO).

The second electrode 123 needs to function as a semi-transmissive reflective film. The second electrode 123 can be formed with magnesium (Mg) or silver (Ag), or a magnesium-silver alloy (MgAg) primarily containing these metals, or moreover, an alloy containing an alkali metal or an alkaline earth metal, or the like.

### Resonator Structure: Second Example

FIG. 22B is a schematic cross-sectional view for describing a second example of the resonator structure.

Also in the second example, the first electrode 121 and the second electrode 123 are formed with a common film thickness in each light-emitting element 12.

Then, also in the second example, the reflector 71 is arranged below the first electrode 121 of the light-emitting element 12 with the optical adjustment layer 72 interposed therebetween. The resonator structure that causes resonance of light generated by the OLED layer 122 is formed between the reflector 71 and the second electrode 123. Similarly to the first example, the reflector 71 is formed with a common film thickness in each light-emitting element 12, and the film thickness of the optical adjustment layer 72 differs in a manner that depends on the color to be displayed by the pixel.

In the first example illustrated in FIG. 22A, the upper surfaces of the reflectors 71 in the light-emitting elements 12_{R}, 12_{G}, and 12_{B} are flush with each other, and the position of the upper surface of the second electrode 123 differs in a manner that depends on the types of the light-emitting elements 12_{R}, 12_{G}, and 12_{B}.

On the other hand, in the second example illustrated in FIG. 22B, the upper surfaces of the second electrodes 123 are flush with each other across the light-emitting elements 12_{R}, 12_{G}, and 12_{B}. In order to make the upper surfaces of the second electrodes 123 flush with each other, in the light-emitting elements 12_{R}, 12_{G}, and 12_{B}, the position of the upper surface of the reflector 71 differs in a manner that depends on the types of the light-emitting elements 12_{R}, 12_{G}, and 12_{B}. Therefore, the lower surfaces of the reflectors 71 (in other words, the upper surface of the underlayer (insulating layer) 73) have a stepped shape according to the type of the light-emitting element 12.

Materials and the like constituting the reflector 71, the optical adjustment layer 72, the first electrode 121, and the second electrode 123 are similar to those described in the first example, and thus the description thereof will be omitted.

### Resonator Structure: Third Example

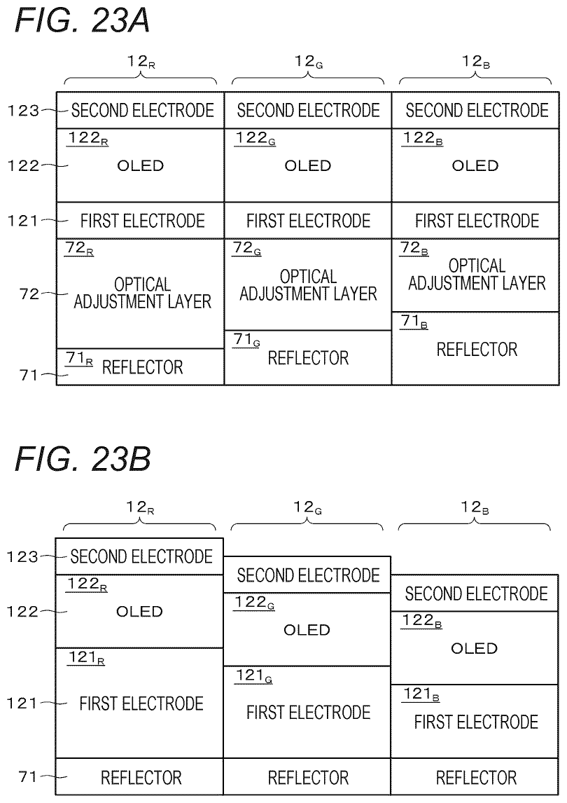

FIG. 23A is a schematic cross-sectional view for describing a third example of the resonator structure. In the following description, the reflectors 71 provided corresponding to the sub-pixels 10R, 10G, and 10B may be referred to as reflectors 71_{R}, 71_{G}, and 71_{B}, respectively.

Also in the third example, the first electrode 121 and the second electrode 123 are formed with a common film thickness in each light-emitting element 12.

Then, also in the third example, the reflector 71 is arranged below the first electrode 121 of the light-emitting element 12 with the optical adjustment layer 72 interposed therebetween. The resonator structure that causes resonance of light generated by the OLED layer 122 is formed between the reflector 71 and the second electrode 123. Similarly to the first and the second examples, the film thickness of the optical adjustment layer 72 differs in a manner that depends on the color to be displayed by the pixel. Then, similarly to the second example, the upper surfaces of the second electrodes 123 are flush with each other across the light-emitting elements 12_{R}, 12_{G}, and 12_{B}.

In the second example illustrated in FIG. 22B, in order to make the upper surfaces of the second electrodes 123 flush with each other, the lower surfaces of the reflectors 71 have a stepped shape according to the type of the light-emitting element 12.

On the other hand, in the third example illustrated in FIG. 23A, the film thickness of the reflector 71 is set to differ in a manner that depends on the types of the light-emitting elements 12_{R}, 12_{G}, and 12_{B}. More specifically, the film thickness is set to make the lower surfaces of the reflector 71_{R}, 71_{G}, and 71_{B} flush with each other.

Materials and the like constituting the reflector 71, the optical adjustment layer 72, the first electrode 121, and the second electrode 123 are similar to those described in the first example, and thus the description thereof will be omitted.

### Resonator Structure: Fourth Example

FIG. 23B is a schematic cross-sectional view for describing a fourth example of the resonator structure. In the following description, the first electrodes 121 provided corresponding to the sub-pixels 10R, 10G, and 10B may be referred to as first electrodes 121_{R}, 121_{G}, and 121_{B}, respectively.

In the first example illustrated in FIG. 22A, the first electrode 121 and the second electrode 123 of each light-emitting element 12 are formed with a common film thickness. Then, the reflector 71 is arranged below the first electrode 121 of the light-emitting element 12 with the optical adjustment layer 72 interposed therebetween.

On the other hand, in the fourth example illustrated in FIG. 23B, the optical adjustment layer 72 is omitted, and the film thickness of the first electrode 121 is set to differ in a manner that depends on the types of the light-emitting elements 12_{R}, 12_{G}, and 12_{B}.

The reflector 71 is formed with a common film thickness in each light-emitting element 12. The film thickness of the first electrode 121 differs in a manner that depends on the color to be displayed by the pixel. Since the first electrodes 121_{R}, 121_{G}, and 121_{B} have different film thicknesses, it is possible to set an optical distance that causes optimum resonance at the wavelength of light corresponding to the color to be displayed.

Materials and the like constituting the reflector 71, the optical adjustment layer 72, the first electrode 121, and the second electrode 123 are similar to those described in the first example, and thus the description thereof will be omitted.

### Resonator Structure: Fifth Example

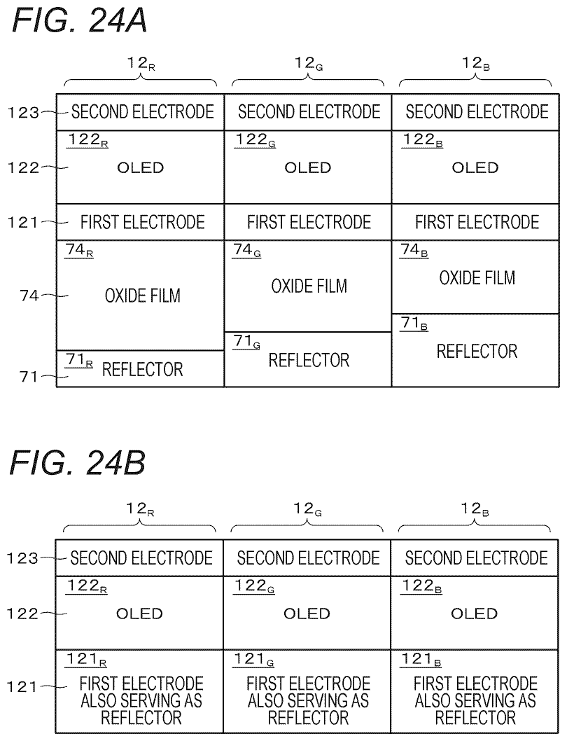

FIG. 24A is a schematic cross-sectional view for describing a fifth example of the resonator structure.

In the first example illustrated in FIG. 22A, the first electrode 121 and the second electrode 123 are formed with a common film thickness in each light-emitting element 12. Then, the reflector 71 is arranged below the first electrode 121 of the light-emitting element 12 with the optical adjustment layer 72 interposed therebetween.

On the other hand, in the fifth example illustrated in FIG. 24A, the optical adjustment layer 72 is omitted, and an oxide film 74 is formed on the surface of the reflector 71 instead. The film thickness of the oxide film 74 is set to differ in a manner that depends on the types of the light-emitting elements 12_{R}, 12_{G}, and 12_{B}. In the following description, the oxide films 74 provided corresponding to the sub-pixels 10R, 10G, and 10B may be referred to as oxide films 74_{R}, 74_{G}, and 74_{B}, respectively.

The film thickness of the oxide film 74 differs in a manner that depends on the color to be displayed by the pixel. Since the oxide films 74_{R}, 74_{G}, and 74_{B} have different film thicknesses, it is possible to set an optical distance that causes optimum resonance at the wavelength of light corresponding to the color to be displayed.

The oxide film 74 is a film obtained by oxidizing the surface of the reflector 71, and includes, for example, aluminum oxide, tantalum oxide, titanium oxide, magnesium oxide, zirconium oxide, or the like. The oxide film 74 functions as an insulating film to adjust the optical path length (optical distance) between the reflector 71 and the second electrode 123.

The oxide film 74 that differs in film thickness in a manner that depends on the types of the light-emitting elements 12_{R}, 12_{G}, and 12_{B} can be formed, for example, as follows.

First, a container is filled with an electrolytic solution, and a substrate on which the reflector 71 is formed is immersed in the electrolytic solution. Furthermore, an electrode is arranged to face the reflector 71.

Then, a positive voltage is applied to the reflector 71 with reference to the electrode to anodize the reflector 71. A film thickness of the oxide film resulting from the anodization is proportional to a voltage value with respect to the electrode. Therefore, the anodization is performed in a state where a voltage according to the type of the light-emitting element 12 is applied to each of the reflectors 71_{R}, 71_{G}, and 71_{B}. This allows for simultaneous formation of the oxide films 74 having different film thicknesses.

Materials and the like constituting the reflector 71, the first electrode 121, and the second electrode 123 are similar to those described in the first example, and thus, the description thereof will be omitted.

### Resonator Structure: Sixth Example

FIG. 24B is a schematic cross-sectional view for describing a sixth example of the resonator structure.

In the sixth example, the light-emitting element 12 includes a stack of the first electrode 121, the OLED layer 122, and the second electrode 123. Note that, in the sixth example, the first electrode 121 is formed to function as both an electrode and a reflector. The first electrode (also serving as a reflector) 121 includes a material having an optical constant selected according to the types of the light-emitting elements 12_{R}, 12_{G}, and 12_{B}. Since the phase shift by the first electrode (also serving as a reflector) 121 varies, it is possible to set an optical distance that causes optimum resonance at the wavelength of light corresponding to the color to be displayed.

The first electrodes (also serving as a reflector) 121 can include an elemental metal such as aluminum (Al), silver (Ag), gold (Au), or copper (Cu), or an alloy primarily containing these metals. For example, the first electrode (also serving as a reflector) 121_{R} of the light-emitting element 12_{R} may include copper (Cu), and the first electrode (also serving as a reflector) 121_{G} of the light-emitting element 12_{G} and the first electrode (also serving as a reflector) 121_{B} of the light-emitting element 12_{B} may include aluminum.

Materials and the like constituting the second electrode 123 are similar to those described in the first example, and thus the description thereof will be omitted.

### Resonator Structure: Seventh Example

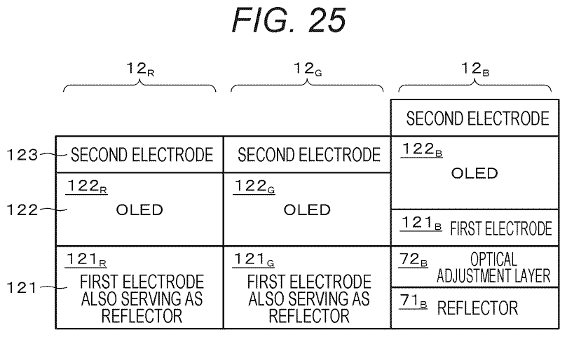

FIG. 25 is a schematic cross-sectional view for describing a seventh example of the resonator structure.

The seventh example basically has a configuration in which the sixth example is applied to the light-emitting elements 12_{R} and 12_{G}, and the first example is applied to the light-emitting elements 12_{B}. Also with this configuration, it is possible to set an optical distance that causes optimum resonance at the wavelength of light corresponding to the color to be displayed.

The first electrodes (also serving as reflectors) 121_{R} and 121_{G} used for the light-emitting elements 12_{R} and 12_{G} can include an elemental metal such as aluminum (Al), silver (Ag), gold (Au), or copper (Cu), or an alloy primarily containing these metals.

Materials and the like constituting the reflector 71_{B}, the optical adjustment layer 72_{B}, and the first electrode 121_{B} used for the light-emitting element 12_{B} are similar to those described in the first example, and thus, the description thereof will be omitted.

### 11. Application Examples

### Electronic Equipment

The display devices 101, 102, 103, 104, and 105 (hereinafter, referred to as “display device 101 and the like”) according to the first to fifth embodiments and the modifications thereof may be provided in various types of electronic equipment. The display device 101 and the like are suitable especially for an eyewear device such as a head-mounted display, an electronic viewfinder of a video camera or a single-lens reflex camera, or the like that requires high resolution and is used near the eyes in an enlarged manner.

### Specific Example 1

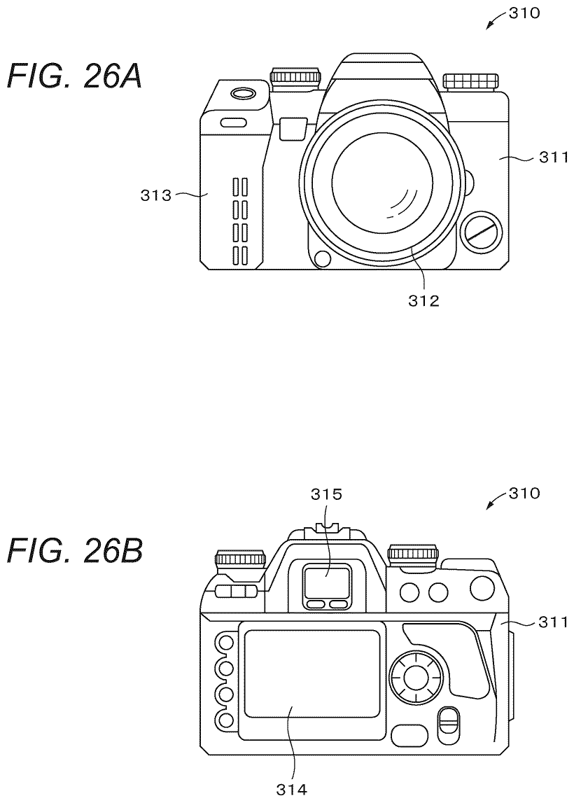

FIGS. 26A and 26B illustrate an example of an external appearance of a digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip portion 313 to be held by a photographer on the front left side.

A monitor 314 is provided at a position shifted to the left side from the center of the back surface of the camera main body 311. An electronic viewfinder (eyepiece window) 315 is provided above the monitor 314. By looking through the electronic viewfinder 315, the photographer can visually recognize an optical image of a subject guided from the imaging lens unit 312, and determine a picture composition. The electronic viewfinder 315 includes any one of the display device 101 and the like described above.

### Specific Example 2

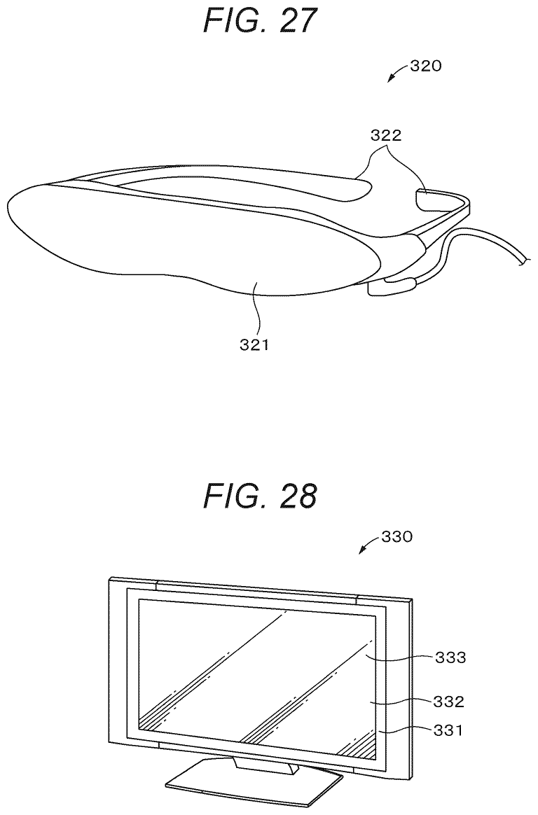

FIG. 27 illustrates an example of an external appearance of a head-mounted display 320. The head-mounted display 320 is an example of the eyewear device. The head-mounted display 320 includes, for example, ear hooking portions 322 for the user to wear the head-mounted display 320 on the head, on both sides of a display unit 321 having a shape of eyeglasses. The display unit 321 includes any one of the display device 101 and the like described above.

### Specific Example 3

FIG. 28 illustrates an example of an external appearance of a television device 330. The television device 330 includes, for example, a video display screen unit 331 including a front panel 332 and a filter glass 333, and the video display screen unit 331 includes any one of the display device 101 and the like described above.

### Specific Example 4

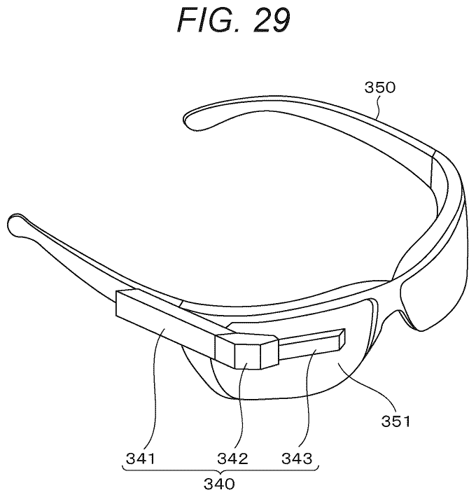

FIG. 29 illustrates an example of an external appearance of a see-through head-mounted display 340. The see-through head-mounted display 340 is an example of the eyewear device. The see-through head-mounted display 340 includes a main body 341, an arm 342, and a lens barrel 343.

The main body 341 is connected to the arm 342 and eyeglasses 350. Specifically, an end of the main body 341 in the long side direction is coupled to the arm 342, and one of the side surfaces of the main body 341 is coupled to the eyeglasses 350 via a connecting member. Note that the main body 341 may be mounted directly on the head of the human body.

The main body 341 includes a control board for controlling operation of the see-through head-mounted display 340, and a display unit. The arm 342 connects the main body 341 and the lens barrel 343 and supports the lens barrel 343. Specifically, the arm 342 is coupled to both the end of the main body 341 and an end of the lens barrel 343 to hold the lens barrel 343. Furthermore, the arm 342 includes a signal line for communicating data related to an image to be provided from the main body 341 to the lens barrel 343.

The lens barrel 343 projects image light provided from the main body 341 through the arm 342 toward the eyes of the user wearing the see-through head-mounted display 340 through an eyeglass 351. In this see-through head-mounted display 340, the display unit of the main body 341 includes any one of the display device 101 and the like described above.

### Specific Example 5

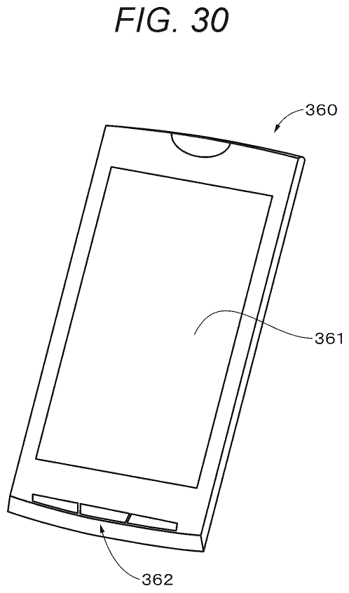

FIG. 30 illustrates an example of an external appearance of a smartphone 360. The smartphone 360 includes a display unit 361 that displays various types of information, an operation unit 362 including buttons for receiving operation inputs from the user, and the like. The display unit 361 includes any one of the display device 101 and the like described above.

### Specific Example 6

The display device 101 and the like described above may be provided in various displays provided in vehicles.

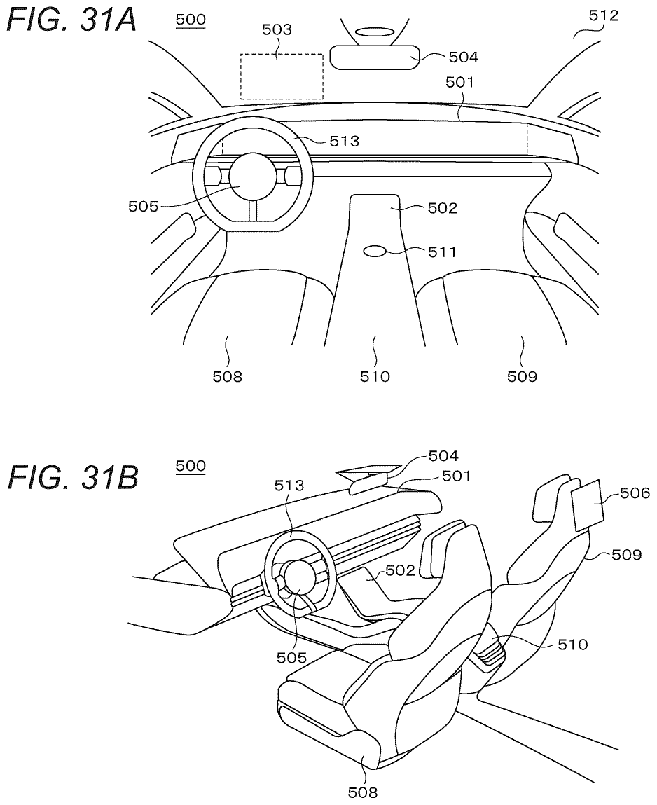

FIGS. 31A and 31B are diagrams illustrating an example of an internal configuration of a vehicle 500 provided with various displays. Specifically, FIG. 31A is a diagram illustrating an example of an internal state of the vehicle 500 as viewed from the rear to the front of the vehicle 500, and FIG. 31B is a diagram illustrating an example of an internal state of the vehicle 500 as viewed from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes any one of the display device 101 and the like described above. For example, all of these displays may include any one of the display device 101 and the like described above.

The center display 501 is arranged on a dashboard to face a driver's seat 508 and a passenger seat 509. FIGS. 31A and 31B illustrate an example of the center display 501 having a horizontally elongated shape extending across the driver's seat 508 and the passenger seat 509, but the screen size and location of the center display 501 are determined as appropriate. The center display 501 can display information sensed by various sensors. As a specific example, the center display 501 can display an image captured by an image sensor, a distance image showing a distance to an obstacle in front of or on a side of the vehicle 500, the distance being measured by a time-of-flight (ToF) sensor, a passenger's body temperature detected by an infrared sensor, and the like. The center display 501 can be used to display, for example, at least one of safety-related information, operation-related information, a lifelog, health-related information, authentication/identification-related information, or entertainment-related information.

The safety-related information is information such as doze sensing, looking-away sensing, sensing of mischief of a child riding together, and presence or absence of wearing of a seat belt, sensing of leaving of an occupant, and is information sensed by a sensor arranged, for example, to overlap with the back surface side of the center display 501. The operation-related information indicates a gesture related to an operation performed by the occupant sensed using a sensor. Gestures to be sensed may include operations of various types of equipment in the vehicle 500. For example, operations of air conditioning equipment, a navigation device, an audiovisual (AV) device, a lighting device, and the like are sensed. The lifelog includes lifelogs of all the occupants. For example, the lifelog includes an action record of each occupant in the vehicle. By acquiring and storing the lifelog, it is possible to check the state of each occupant at the time of an accident. The health-related information indicates the occupant's body temperature sensed by a sensor such as a temperature sensor, and the health condition of the occupant is estimated on the basis of the sensed body temperature. Alternatively, the face of the occupant may be imaged by using an image sensor, and the health condition of the occupant may be estimated from the imaged facial expression. Moreover, automatic voice conversations may be made with the occupant, and the health condition of the occupant may be estimated on the basis of the content of a response from the occupant. The authentication/identification-related information includes information regarding a keyless entry function using facial authentication with a sensor, and an automatic seat height and position adjustment function through facial identification. The entertainment-related information includes information regarding a function of detecting, with a sensor, operation information about an AV device being used by the occupant, and a function of recognizing the face of the occupant with a sensor and providing content suitable for the occupant through the AV device.

The console display 502 can be used, for example, to display lifelog information. The console display 502 is arranged near a shift lever 511 of a center console 510 between the driver's seat 508 and the passenger seat 509. The console display 502 can also display information sensed by various sensors. Furthermore, the console display 502 may display an image of the surroundings of the vehicle captured with an image sensor, or may display a distance image showing a distance to an obstacle present in the surroundings of the vehicle.

The head-up display 503 is virtually displayed behind a windshield 512 in front of the driver's seat 508. The head-up display 503 can be used to display at least one of the safety-related information, the operation-related information, the lifelog, the health-related information, the authentication/identification-related information, or the entertainment-related information, for example. Since the head-up display 503 is virtually arranged in front of the driver's seat 508 in many cases, the head-up display 503 is suitable for displaying information directly related to operation of the vehicle 500, such as the speed and the remaining fuel (battery) level of the vehicle 500.

The digital rearview mirror 504 can display not only the rear of the vehicle 500 but also the state of an occupant in the rear seat, so that with a sensor arranged on the back surface side of the digital rearview mirror 504, the digital rearview mirror 504 can be used to display the lifelog information, for example.

The steering wheel display 505 is arranged near the center of a steering wheel 513 of the vehicle 500. The steering wheel display 505 can be used to display at least one of the safety-related information, the operation-related information, the lifelog, the health-related information, the authentication/identification-related information, or the entertainment-related information, for example. In particular, since the steering wheel display 505 is located close to the driver's hand, the steering wheel display 505 is suitable for displaying the lifelog information such as the driver's body temperature, or for displaying information regarding the operation of the AV device, air conditioning equipment, or the like.

The rear entertainment display 506 is attached to the back surface side of the driver's seat 508 or the passenger seat 509, and is for the occupant in the rear seat to enjoy viewing/listening. The rear entertainment display 506 can be used to display at least one of the safety-related information, the operation-related information, the lifelogs, the health-related information, the authentication/identification-related information, or the entertainment-related information, for example. In particular, as the rear entertainment display 506 is located in front of the occupant in the rear seat, information related to the occupant in the rear seat is displayed. For example, information regarding the operation of the AV device or air conditioning equipment may be displayed, or a result of measurement of the body temperature or the like of the occupant in the rear seat with a temperature sensor may be displayed on the display.

A sensor may be arranged on the back surface side of the display device 101 and the like, so that the distance to an object present in the surroundings can be measured. Optical distance measurement methods are roughly classified into a passive type and an active type. By the method of the passive type, distance measurement is performed by receiving light from an object, without projecting light from a sensor to the object. Examples of the method of the passive type include a lens focus method, a stereo method, a monocular vision method, and the like. By the method of the active type, distance measurement is performed by projecting light onto an object, and receiving reflected light from the object with a sensor to measure the distance. Examples of the method of the active type include an optical radar method, an active stereo method, an illuminance difference stereo method, a moire topography method, an interference method, and the like. The display device 101 and the like described above can be used in distance measurement by any of these methods. The passive or active distance measurement described above can be performed by using the sensor arranged on the back surface side of the display device 101 and the like described above.

### REFERENCE SIGNS LIST

10R, 10G, 10B Sub-pixel
11 Drive substrate
111 Substrate
112 Insulating layer
113, 115 Wiring
114, 116 Contact
12W, 12R, 12G, 12B Light-emitting element
121 Anode
122 OLED layer
123, 126 Cathode
124 Common electrode
125 Contact
13 Insulating layer
14 Protective layer
15 Color filter
15FR Red filter portion
15FG Green filter portion
15FB Blue filter portion
16 Filling resin layer
17 Seal portion
18 Cover glass
19 Contact electrode
191 Protrusion
192 Protrusion group
192a First protrusion
192b Second protrusion
193 Protrusion group
193a Protrusion
21 First protective layer
22 Second protective layer
23 Planarization layer
24 Lens array
241 Lens
101, 102, 103, 104, 105, 601 Display device
310 Digital still camera
320 Head-mounted display
330 Television device
340 See-through head-mounted display
360 Smartphone
500 Vehicle
RE1 Effective pixel region
RE2 Peripheral region

What is claimed is:

1. A light-emitting device, comprising:
a plurality of light-emitting elements in a light-emitting region;
a contact electrode provided in a peripheral region located around the light-emitting region; and
a first electrode extending from the light-emitting region to the peripheral region and connected to the contact electrode, wherein
the contact electrode includes a plurality of first structures at a portion where the first electrode is connected, and
a plurality of the first structures extends in a direction away from the light-emitting region.

2. The light-emitting device according to claim 1, wherein
a plurality of the first structures includes at least one of a plurality of first recesses or a plurality of first protrusions.

3. The light-emitting device according to claim 1, wherein
the contact electrode has a loop shape surrounding the light-emitting region.

4. The light-emitting device according to claim 1, wherein
the direction away from the light-emitting region includes a direction perpendicular to an outer periphery of the light-emitting region or a direction oblique to the outer periphery of the light-emitting region.

5. The light-emitting device according to claim 1, wherein
a plurality of the first structures is arranged in a circumferential direction of an outer periphery of the light-emitting region, and
a distance between the first structures adjacent to each other on an inner peripheral side of the peripheral region is greater than a distance between the first structures adjacent to each other on an outer peripheral side of the peripheral region.

6. The light-emitting device according to claim 1, wherein
the contact electrode further includes a plurality of second structures at the portion where the first electrode is connected,
a plurality of the second structures extends in a direction approximately perpendicular to an extending direction of the first structures, and
a plurality of the first structures is provided closer to the light-emitting region than a plurality of the second structures.

7. The light-emitting device according to claim 1, wherein
the light-emitting region includes an effective pixel region, and
the first electrode includes a cathode.

8. The light-emitting device according to claim 1, further comprising:
a plurality of second electrodes provided in the light-emitting region; and
an organic light-emitting layer provided between a plurality of the second electrodes and the first electrode.

9. The light-emitting device according to claim 1, further comprising:
a plurality of third electrodes provided in the light-emitting region;
a plurality of fourth electrodes provided in the light-emitting region; and
a plurality of organic light-emitting layers provided in the light-emitting region, wherein
each of the organic light-emitting layers is provided between a corresponding one of the third electrodes and a corresponding one of the fourth electrodes, and
the first electrode is connected to a plurality of the fourth electrodes.

10. A light-emitting device, comprising:
a plurality of light-emitting elements in a light-emitting region;
a contact electrode provided in a peripheral region located around the light-emitting region; and
a first electrode extending from the light-emitting region to the peripheral region and connected to the contact electrode, wherein
the contact electrode includes a plurality of structure groups at a portion where the first electrode is connected,
a plurality of the structure groups is arranged at least in a circumferential direction of an outer periphery of the light-emitting region,
each of the structure groups includes a plurality of structures, and
the structure groups adjacent to each other in the circumferential direction are separated from each other.

11. The light-emitting device according to claim 10, wherein
a plurality of the structures includes at least one of a plurality of recesses or a plurality of protrusions.

12. The light-emitting device according to claim 10, wherein
a distance between the structure groups adjacent to each other in the circumferential direction is greater than a distance between the structures adjacent to each other.

13. The light-emitting device according to claim 10, wherein
a plurality of the structures is arranged two-dimensionally in the circumferential direction and a direction approximately perpendicular to the circumferential direction, and
a distance between the structure groups adjacent to each other in the circumferential direction is greater than a distance between the structures adjacent to each other in the circumferential direction.

14. The light-emitting device according to claim 10, wherein
a plurality of the structure groups is arranged two-dimensionally in the circumferential direction and a direction approximately perpendicular to the circumferential direction, and
the structure groups adjacent to each other in the direction approximately perpendicular to the circumferential direction are separated from each other.

15. The light-emitting device according to claim 14, wherein
a plurality of the structures is arranged two-dimensionally in the circumferential direction and the direction approximately perpendicular to the circumferential direction,
a distance between the structure groups adjacent to each other in the circumferential direction is greater than a distance between the structures adjacent to each other in the circumferential direction, and
a distance between the structure groups adjacent to each other in the direction approximately perpendicular to the circumferential direction is greater than a distance between the structures adjacent to each other in the direction approximately perpendicular to the circumferential direction.

16. The light-emitting device according to claim 11, wherein
a plurality of the structures is arranged two-dimensionally,
a plurality of the recesses becomes shallower from an outer periphery toward an inner periphery of the peripheral region, and
a plurality of the protrusions becomes lower from the outer periphery toward the inner periphery of the peripheral region.

17. The light-emitting device according to claim 10, wherein
a plurality of the structures is arranged two-dimensionally,
a plurality of the structures has at least one step, and
a number of the steps of a plurality of the structures increases from an outer periphery toward an inner periphery of the peripheral region.

18. The light-emitting device according to claim 10, wherein
a plurality of the structures is arranged two-dimensionally, and
inclination angles of side surfaces of a plurality of the structures decrease from an outer periphery toward an inner periphery of the peripheral region.

19. The light-emitting device according to claim 10, wherein
a plurality of the structures has a dot shape in plan view.

20. Electronic equipment comprising the light-emitting device according to claim 1.
